(19) United States
(12) Patent Application Publication
(10) Pub. No.: US 2012/0000533 A1
(43) Pub. Date: Jan. 5, 2012

(54) PHOTOELECTRIC CONVERSION DEVICE COMPRISING HYDROXAMIC ACID OR A SALT THEREOF AS ADDITIVE AND PROCESS FOR PRODUCING SAME

(75) Inventors: Neil Gregory PSCHIRER, Mainz (DE); Felix EICKEMEYER, Heidelberg (DE); Jan SCHOENEBOOM, Mannheim (DE); Rüdiger SENS, Ludwigshafen (DE); Peter ERK, Frankenthal (DE); Helmut REICHELT, Neustadt (DE); Hermann BERGMANN, Singapore (SG)

(73) Assignee: BASF SE, Ludwigshafen (DE)

(21) Appl. No.: 13/170,667

(22) Filed: Jun. 28, 2011

Related U.S. Application Data
(60) Provisional application No. 61/359,388, filed on Jun. 29, 2010.

(51) Int. Cl. H01L 31/0216; H01L 51/40

(52) U.S. Cl. 136/263; 438/82; 438/85; 257/E51.012

(57) ABSTRACT

The present invention pertains to a process for producing a photoelectric conversion device comprising a dye-sensitized metal oxide semiconductor which is treated with an essentially transparent hydroxamic acid or an essentially transparent salt thereof. The invention also relates to a photoelectric conversion device obtainable by the process of the invention and to a photoelectric cell, especially a solar cell, comprising the photoelectric conversion device. Moreover, the invention relates to the use of an essentially transparent hydroxamic acid or an essentially transparent salt thereof for enhancing the energy conversion efficiency η of dye-sensitized photoelectric conversion devices.

The present invention pertains to a process for producing a photoelectric conversion device comprising a dye-sensitized metal oxide semiconductor which is treated with an essentially transparent hydroxamic acid or an essentially transparent salt thereof. The invention also relates to a photoelectric conversion device obtainable by the process of the invention and to a photoelectric cell, especially a solar cell, comprising the photoelectric conversion device. Moreover, the invention relates to the use of an essentially transparent hydroxamic acid or an essentially transparent salt thereof for enhancing the energy conversion efficiency η of dye-sensitized photoelectric conversion devices.

### BACKGROUND OF THE INVENTION

Photoelectric conversion devices using a semiconductor metal oxide sensitized by a dye, hereinafter referred to as “dye-sensitized photoelectric conversion device,” and materials and producing methods therefore have been disclosed for example in U.S. Pat. Nos. 4,927,721, 5,350,644, 6,245,988, WO 2007/054470 and WO 2009/013258.

The dye-sensitized photoelectric conversion devices can be produced at reduced costs as compared to silicium-based cells because an inexpensive metal oxide semiconductor such as titanium dioxide can be used therefor without purification to a high purity.

The overall performance of a photoelectric conversion device, such as used for instance in a solar cell, is characterized by several parameters such as the open circuit voltage (V_{oc}), the short circuit current (I_{sc}), the fill factor (FF) and the energy conversion efficiency ( [symbol] ) resulting therefrom (see e.g. Jenny Nelson “The Physics of Solar Cells” (2003), Imperial College Press).

As conventional dye-sensitized photoelectric conversion devices do not necessarily have a sufficiently high photoelectric conversion efficiency, many attempts have been undertaken to further improve these devices.

To this end EP 1 473 745 proposes the co-adsorption of a compound having a hydrophobic part and an anchoring group together with a dye to a semi-conductive metal oxide which is described to result in an increase of the open circuit voltage V_{oc}.

U.S. Pat. No. 6,586,670 reports that a dye sensitized photoelectric conversion device using a semi-conductive metal oxide treated with a particular urea compound is excellent in energy conversion efficiency h.

The use of dyes comprising hydroxamate moieties as anchor groups for the preparation of photoelectric conversion devices is known, e.g. from WO99/03868, WO2008/029523 and WO2006/010290. However, in the context of photoelectric conversion, hydroxamate compounds so far have not been reported to be employed for any other purposes than binding light-harvesting dyes.

There is still an ongoing need to further improve the performance of dye-sensitized photoelectric conversion devices, in particular their energy conversion efficiency h.

It is therefore the object of the present invention to provide a photoelectric conversion device having an enhanced energy conversion efficiency h, a solar cell comprising the device, and processes for producing the same.

The object is achieved by the processes and devices described in detail below.

The present invention relates to a process for producing a dye-sensitized photoelectric conversion device comprising a photosensitive layer containing at least one semiconductive metal oxide on which at least one chromophoric substance is adsorbed, wherein said semi-conductive metal oxide is treated with at least one hydroxamic acid or at least one salt thereof, which are essentially transparent in the electromagnetic wavelength range of 400 to 1000 nm, preferably 400 to 800 nm.

Surprisingly, the addition of such a hydroxamic acid/hydroxamate additive to the dye-sensitized photoelectric conversion device and solar cells comprising such devices leads to a dramatic increase in device performance, even in cases where less dye is present in the cell to absorb light.

The present invention also relates to a dye-sensitized photoelectric conversion device obtainable by the process of the invention and characterized as described below and to a photoelectric cell, preferably a solar cell, comprising such a device. The photoelectric cell comprises the dye-sensitized photoelectric conversion device and is part of an electric circuit. The invention moreover relates to the use of hydroxamic acids and/or of salts thereof as defined above and below for enhancing the energy conversion efficiency η of dye-sensitized photoelectric conversion devices and also of photoelectric cells, especially solar cells comprising them.

The remarks made below to the process of the invention apply also to the dyesensitized photoelectric conversion device and the photoelectric cell of the invention.

“Essentially transparent” means in this context that the hydroxamic acid or its salt essentially does not absorb, and preferably essentially does neither reflect, electromagnetic radiation in the wavelength range of 400 to 1000 nm, preferably of 400 to 800 nm.

“Essentially does not absorb and preferably essentially does neither reflect” in said wavelength range means that the hydroxamic acid or its salt has an extinction coefficient, as measured in methylene chloride, of below 10³ L·mol⁻¹·cm⁻¹, preferably of below 10² L·mol⁻¹·cm⁻¹ in the electromagnetic wavelength range of 400 to 1000 nm, preferably of 400 to 800 nm.

If TiO₂ is used as the semi-conductive metal oxide, the hydroxamic acids or their salts might give rise to very weak charge transfer absorption bands which overlap with TiO₂ absorption. The extinction coefficient of these charge transfer bands is at 400 nm <1000 l/(mol·cm) and practically does not contribute to the photocurrent of the photovoltaic cell.

The process and the devices of the present invention are associated with several advantages. For instance, the process of the invention allows for the inexpensive and easy preparation of durable photoelectric conversion devices that feature excellent energy conversion efficiencies [symbol] and are highly suitable for being used in solar cells.

In the context of the present invention, the terms used generically are defined as follows:

The term “cation equivalent” designates an equivalent of a cation which can neutralize a hydroxamate anion (R¹—C(O)—NR²—O⁻). For example, the Ca²⁺ ion can bind to 2 hydroxamate groups, i.e. ½ Ca²⁺ corresponds to M⁺ in formula (I′), in case the cation equivalent is a calcium ion equivalent.

Unless stated otherwise, the terms “alkyl”, “alkoxy”, “alkylthio”, “haloalkyl”, “haloalkoxy”, “haloalkylthio”, “alkenyl”, “alkadienyl”, “alkatrienyl”, “alkynyl”, “alkylene” and radicals derived therefrom always include both unbranched and branched “alkyl”, “alkoxy”, “alkylthio”, “haloalkyl”, “haloalkoxy”, “haloalkylthio”, “alkenyl”, “alkadienyl”, “alkatrienyl”, “alkynyl” and “alkylene”, respectively.

The prefix Cₙ—Cₘ— indicates the respective number of carbons in the hydrocarbon unit. Unless indicated otherwise, halogenated substituents preferably have one to five identical or different halogen atoms, especially fluorine atoms or chlorine atoms. C₀-Alkylene or (CH₂)₀ or similar expressions in the context of the description designate, unless indicated otherwise, a single bond.

The term “halogen” designates in each case, fluorine, bromine, chlorine or iodine, specifically fluorine, chlorine or bromine.

Alkyl, and the alkyl moieties for example in alkoxy, alkylthio, arylalkyl, hetarylalkyl, cycloalkylalkyl or alkoxyalkyl: saturated, straight-chain or branched hydrocarbon radicals having one or more C atoms, e.g. 1 to 4, 1 to 6, 1 to 8, 1 to 10, 1 to 12 or 1 to 18 carbon atoms, e.g. C₁-C₄-alkyl such as methyl, ethyl, propyl, 1-methylethyl (isopropyl), butyl, 1-methylpropyl (sec-butyl), 2-methylpropyl (isobutyl) or 1,1-dimethylethyl (tertbutyl), C₁-C₆-alkyl such as methyl, ethyl, propyl, 1-methylethyl, butyl, 1-methylpropyl, 2-methylpropyl, 1,1-dimethylethyl, pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl or 1-ethyl-2-methylpropyl, C₁-C₈-alkyl such as the radicals mentioned before for C₁-C₆-alkyl and further also heptyl, 2-methyl-hexyl, octyl or 2,4-diethylhexyl and further positional isomers thereof, C₁-C₁₀-alkyl such as the radicals mentioned before for C₁-C₈-alkyl and further also nonyl, decyl, 2,4-dimethyl-octyl and further positional isomers thereof, C₁-C₁₂-alkyl such as the radicals mentioned before for C₁-C₁₀-alkyl and further also undecyl, dodecyl, 5,7-dimethyldecy, 3-methylundecyl and further positional isomers thereof, and C₁-C₁₈-alkyl such as the radicals mentioned before for C₁-C₁₂-alkyl and further also tridecyl, tetradecyl, pentadecyl, hexadecyl, heptadecyl, octadecyl and the positional isomers thereof.

C₃-C₁₀-Alkyl is a saturated, straight-chain or branched hydrocarbon radical having 3 to 10 carbon atoms. Examples are propyl, 1-methylethyl (isopropyl), butyl, 1-methylpropyl (sec-butyl), 2-methylpropyl (isobutyl), 1,1-dimethylethyl (tert-butyl), pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, heptyl, 2-methylhexyl, octyl, 2,4-diethylhexyl, nonyl, decyl, 2,4-dimethyl-octyl and further positional isomers thereof.

C₃-C₁₂-Alkyl is a saturated, straight-chain or branched hydrocarbon radical having 3 to 12 carbon atoms. Examples are, apart those mentioned above for C₃-C₁₀-alkyl, undecyl, dodecyl, 5,7-dimethyldecy, 3-methylundecyl and further positional isomers thereof.

Haloalkyl: an alkyl radical having ordinarily 1 to 4, 1 to 6, 1 to 8, 1 to 10, 1 to 12 or 1 to 18 carbon atoms as mentioned above, whose hydrogen atoms are partly or completely replaced by halogen atoms such as fluorine, chlorine, bromine and/or iodine, e.g. chloromethyl, dichloromethyl, trichloromethyl, fluoromethyl, difluoromethyl, trifluoromethyl, chlorofluoromethyl, dichlorofluoromethyl, chlorodifluoromethyl, 2-fluoroethyl, 2-chloroethyl, 2-bromoethyl, 2-iodoethyl, 2,2-difluoroethyl, 2,2,2-trifluoroethyl, 2-chloro-2-fluoroethyl, 2-chloro-2,2-difluoroethyl, 2,2-dichloro-2-fluoroethyl, 2,2,2-trichloroethyl, pentafluoroethyl, 2-fluoropropyl, 3-fluoropropyl, 2,2-difluoropropyl, 2,3-difluoropropyl, 2-chloropropyl, 3-chloropropyl, 2,3-dichloropropyl, 2-bromopropyl, 3-bromopropyl, 3,3,3-trifluoropropyl, 3,3,3-trichloropropyl, 2,2,3,3,3-pentafluoropropyl, heptafluoropropyl, 1-(fluoromethyl)-2-fluoroethyl, 1-(chloromethyl)-2-chloroethyl, 1-(bromomethyl)-2-bromoethyl, 4-fluorobutyl, 4-chlorobutyl, 4-bromobutyl, nonafluorobutyl, 3-chloropentyl, 2-(fluoromethyl)-hexyl, 4-bromoheptyl, 1-(chloromethyl)-5-chlorooctyl, 2,3-difluorononyl, 10-bromodecyl, 2,3,6-trifluoroundecyl, 2-chlorododecyl.

Cycloalkyl, and the cycloalkyl moieties for example in cycloalkoxy or cycloalkyl-C₁-C₆-alkyl: monocyclic, saturated hydrocarbon groups having three or more C atoms, e.g. 3 to 7 carbon ring members, for example 3, 4, 5, 6 or 7 carbon ring members, such as cyclopropyl, cyclobutyl, cyclopentyl, cyclohexyl or cycloheptyl.

Alkenyl, and alkenyl moieties for example in aryl-(C₂-C₆)-alkenyl: monounsaturated, straight-chain or branched hydrocarbon radicals having two or more C atoms, e.g. 2 to 4, 2 to 6 or 2 to 12 carbon atoms and one double bond in any position, e.g. C₂-C₆-alkenyl such as ethenyl, 1-propenyl, 2-propenyl, 1-methylethenyl, 1-butenyl, 2-butenyl, 3-butenyl, 1-methyl-1-propenyl, 2-methyl-1-propenyl, 1-methyl-2-propenyl, 2-methyl-2-propenyl, 1-pentenyl, 2-pentenyl, 3-pentenyl, 4-pentenyl, 1-methyl-1-butenyl, 2-methyl-1-butenyl, 3-methyl-1-butenyl, 1-methyl-2-butenyl, 2-methyl-2-butenyl, 3-methyl-2-butenyl, 1-methyl-3-butenyl, 2-methyl-3-butenyl, 3-methyl-3-butenyl, 1,1-dimethyl-2-propenyl, 1,2-dimethyl-1-propenyl, 1,2-dimethyl-2-propenyl, 1-ethyl-1-propenyl, 1-ethyl-2-propenyl, 1-hexenyl, 2-hexenyl, 3-hexenyl, 4-hexenyl, 5-hexenyl, 1-methyl-1-pentenyl, 2-methyl-1-pentenyl, 3-methyl-1-pentenyl, 4-methyl-1-pentenyl, 1-methyl-2-pentenyl, 2-methyl-2-pentenyl, 3-methyl-2-pentenyl, 4-methyl-2-pentenyl, 1-methyl-3-pentenyl, 2-methyl-3-pentenyl, 3-methyl-3-pentenyl, 4-methyl-3-pentenyl, 1-methyl-4-pentenyl, 2-methyl-4-pentenyl, 3-methyl-4-pentenyl, 4-methyl-4-pentenyl, 1,1-dimethyl-2-butenyl, 1,1-dimethyl-3-butenyl, 1,2-dimethyl-1-butenyl, 1,2-dimethyl-2-butenyl, 1,2-dimethyl-3-butenyl, 1,3-dimethyl-1-butenyl, 1,3-dimethyl-2-butenyl, 1,3-dimethyl-3-butenyl, 2,2-dimethyl-3-butenyl, 2,3-dimethyl-1-butenyl, 2,3-dimethyl-2-butenyl, 2,3-dimethyl-3-butenyl, 3,3-dimethyl-1-butenyl, 3,3-dimethyl-2-butenyl, 1-ethyl-1-butenyl, 1-ethyl-2-butenyl, 1-ethyl-3-butenyl, 2-ethyl-1-butenyl, 2-ethyl-2-butenyl, 2-ethyl-3-butenyl, 1,1,2-trimethyl-2-propenyl, 1-ethyl-1-methyl-2-propenyl, 1-ethyl-2-methyl-1-propenyl, 1-ethyl-2-methyl-2-propenyl.

Alkynyl: straight-chain or branched hydrocarbon groups having two or more C atoms, e.g. 2 to 4, 2 to 6 or 2 to 12 carbon atoms and one or two triple bonds in any position but nonadjacent, e.g. C₂-C₆-alkynyl such as ethynyl, 1-propynyl, 2-propynyl, 1-butynyl, 2-butynyl, 3-butynyl, 1-methyl-2-propynyl, 1-pentynyl, 2-pentynyl, 3-pentynyl, 4-pentynyl, 1-methyl-2-butynyl, 1-methyl-3-butynyl, 2-methyl-3-butynyl, 3-methyl-1-butynyl, 1,1-dimethyl-2-propynyl, 1-ethyl-2-propynyl, 1-hexynyl, 2-hexynyl, 3-hexynyl, 4-hexynyl, 5-hexynyl, 1-methyl-2-pentynyl, 1-methyl-3-pentynyl, 1-methyl-4-pentynyl, 2-methyl-3-pentynyl, 2-methyl-4-pentynyl, 3-methyl-1-pentynyl, 3-methyl-4-pentynyl, 4-methyl-1-pentynyl, 4-methyl-2-pentynyl, 1,1-dimethyl-2-butynyl, 1,1-dimethyl-3-butynyl, 1,2-dimethyl-3-butynyl, 2,2-dimethyl-3-butynyl, 3,3-dimethyl-1-butynyl, 1-ethyl-2-butynyl, 1-ethyl-3-butynyl, 2-ethyl-3-butynyl, 1-ethyl-1-methyl-2-propynyl.

Alkadienyl: straight or branched alkyl group having 4 or more carbon atoms, e.g. 4 to 6, 4 to 10 or 4 to 12 carbon atoms and two double bonds in any position but nonadjacent, such as 2,4-butadienyl, 2,4-pentadienyl, 2-methyl-2,4-pentadienyl, 2,4-hexadienyl, 2,4-heptadienyl, 2,4-octadienyl, 2,4-nonadienyl, 2,4-decadienyl, 1,3-butadienyl, 1,3-pentadienyl, 2-methyl-1,3-pentadienyl, 1,3-hexadienyl, 1,3-heptadienyl, 1,3-octadienyl, 1,3-nonadienyl, 1,3-decadienyl and the like.

Alkatrienyl: straight or branched alkyl group having 6 or more carbon atoms, e.g. 6 to 8, 6 to 10 or 6 to 12 carbon atoms and three double bonds in any position but nonadjacent, such as 2,4,6-hexatrienyl, 2,4,6-heptatrienyl, 2-methyl-2,4,6-heptatrienyl, 2,4,6-octatrienyl, 2,4,6-nonatrienyl, 2,4,6-decatrienyl, 2,4,6-undecatrienyl, 2,4,6-dodecatrienyl, 1,3,5-hexatrienyl, 1,3,5-heptatrienyl, 2-methyl-1,3,5-heptatrienyl, 1,3,5-octatrienyl, 1,3,5-nonatrienyl, 1,3,5-decatrienyl, 1,3,5-undecatrienyl, 1,3,5-dodecatrienyl and the like.

Radicals where CH₂ groups are replaced by O, NH, or S denote hydrocarbon radicals in which one or more nonadjacent —CH₂— groups independently of one another are replaced by —O—, —NH— or —S—. Examples of such radicals are —CH₂—CH₂—O—CH₃, —CH₂—CH₂—O—CH₂—CH₂—O—CH₃, —CH₂—CH₂—O—CH₂—CH₂—NH—CH₃, —CH₂═CH₂—CH₂—O—CH₃, —CH₂—CH₂—S—CH₃ and the like.

Alkoxy or alkoxy moieties for example in alkoxyalkyl:

Alkyl as defined above having preferably 1 to 4, 1 to 6 or 1 to 12 C atoms, which is linked via an O atom: e.g. methoxy, ethoxy, n-propoxy, 1-methylethoxy, butoxy, 1-methylpropoxy, 2-methylpropoxy or 1,1-dimethylethoxy, pentoxy, 1-methylbutoxy, 2-methylbutoxy, 3-methylbutoxy, 1,1-dimethylpropoxy, 1,2-dimethylpropoxy, 2,2-dimethylpropoxy, 1-ethylpropoxy, hexoxy, 1-methylpentoxy, 2-methylpentoxy, 3-methylpentoxy, 4-methylpentoxy, 1,1-dimethylbutoxy, 1,2-dimethylbutoxy, 1,3-dimethylbutoxy, 2,2-dimethylbutoxy, 2,3-dimethylbutoxy, 3,3-dimethylbutoxy, 1-ethylbutoxy, 2-ethylbutoxy, 1,1,2-trimethylpropoxy, 1,2,2-trimethylpropoxy, 1-ethyl-1-methylpropoxy or 1-ethyl-2-methylpropoxy, pentoxy, hexoxy, heptoxy, 2-methylhexoxy, 4-propyl-heptoxy, octoxy, 2,4-diethyloctoxy, nonoxy, 3,4-dimethylnonoxy, decoxy, 3-ethyl-decoxy.

C₃-C₁₀-Alkoxy is a saturated, straight-chain or branched hydrocarbon radical having 3 to 10 carbon atoms. Examples are propoxy, 1-methylethoxy (isopropoxy), butoxy, 1-methylpropoxy (sec-butoxy), 2-methylpropoxy (isobutoxy), 1,1-dimethylethoxy (tertbutoxy), pentoxy, 1-methylbutoxy, 2-methylbutoxy, 3-methylbutoxy, 2,2-dimethylpropoxy, 1-ethylpropoxy, hexyloxy, 1,1-dimethylpropoxy, 1,2-dimethylpropoxy, 1-methylpentoxy, 2-methylpentoxy, 3-methylpentoxy, 4-methylpentoxy, 1,1-dimethylbutoxy, 1,2-dimethylbutoxy, 1,3-dimethylbutoxy, 2,2-dimethylbutoxy, 2,3-dimethylbutoxy, 3,3-dimethylbutoxy, 1-ethylbutoxy, 2-ethylbutoxy, 1,1,2-trimethylpropoxy, 1,2,2-trimethylpropoxy, 1-ethyl-1-methylpropoxy, 1-ethyl-2-methylpropoxy, heptyloxy, 2-methyl-hexyloxy, octyloxy, 2,4-diethylhexyloxy, nonyloxy, decyloxy, 2,4-dimethyl-octyloxy and further positional isomers thereof.

C₃-C₁₂-Alkoxy is a saturated, straight-chain or branched hydrocarbon radical having 3 to 12 carbon atoms. Examples are, apart those mentioned above for C₃-C₁₀-alkoxy, undecyloxy, dodecyloxy, 5,7-dimethyldecyloxy, 3-methylundecyloxy and further positional isomers thereof.

Haloalkoxy: alkoxy as described above, in which the hydrogen atoms of these groups are partly or completely replaced by halogen atoms, i.e. for example C₁-C₆-haloalkoxy, such as chloromethoxy, dichloromethoxy, trichloromethoxy, fluoromethoxy, difluoromethoxy, trifluoromethoxy, chlorofluoromethoxy, dichlorofluoromethoxy, chlorodifluoromethoxy, 2-fluoroethoxy, 2-chloroethoxy, 2-bromoethoxy, 2-iodoethoxy, 2,2-difluoroethoxy, 2,2,2-trifluoroethoxy, 2-chloro-2-fluoroethoxy, 2-chloro-2,2-difluoroethoxy, 2,2-dichloro-2-fluoroethoxy, 2,2,2-trichloroethoxy, pentafluoroethoxy, 2-fluoropropoxy, 3-fluoropropoxy, 2,2-difluoropropoxy, 2,3-difluoropropoxy, 2-chloropropoxy, 3-chloropropoxy, 2,3-dichloropropoxy, 2-bromopropoxy, 3-bromopropoxy, 3,3,3-trifluoropropoxy, 3,3,3-trichloropropoxy, 2,2,3,3,3-pentafluoropropoxy, heptafluoropropoxy, 1-(fluoromethyl)-2-fluoroethoxy, 1-(chloromethyl)-2-chloroethoxy, 1-(bromomethyl)-2-bromoethoxy, 4-fluorobutoxy, 4-chlorobutoxy, 4-bromobutoxy, nonafluorobutoxy, 5-fluoro-1-pentoxy, 5-chloro-1-pentoxy, 5-bromo-1-pentoxy, 5-iodo-1-pentoxy, 5,5,5-trichloro-1-pentoxy, undecafluoropentoxy, 6-fluoro-1-hexoxy, 6-chloro-1-hexoxy, 6-bromo-1-hexoxy, 6-iodo-1-hexoxy, 6,6,6-trichloro-1-hexoxy or dodecafluorohexoxy, specifically chloromethoxy, fluoromethoxy, difluoromethoxy, trifluoromethoxy, 2-fluoroethoxy, 2-chloroethoxy or 2,2,2-trifluoroethoxy.

Alkoxyalkyl: an alkyl radical ordinarily having 1 to 4 C atoms, in which one hydrogen atom is replaced by an alkoxy radical ordinarily having 1 to 6 or 1 to 4 C atoms. Examples thereof are CH₂—OCH₃, CH₂—OC₂H₅, n-propoxymethyl, CH₂—OCH(CH₃)₂, n-butoxymethyl, (1-methylpropoxy)methyl, (2-methylpropoxy)methyl, CH₂—OC(CH₃)₃, 2-(methoxy)ethyl, 2-(ethoxy)ethyl, 2-(n-propoxy)ethyl, 2-(1-methylethoxy)ethyl, 2-(n-butoxy)ethyl, 2-(1-methylpropoxy)ethyl, 2-(2-methylpropoxy)ethyl, 2-(1,1-dimethylethoxy)ethyl, 2-(methoxy)propyl, 2-(ethoxy)propyl, 2-(n-propoxy)propyl, 2-(1-methylethoxy)propyl, 2-(n-butoxy)propyl, 2-(1-methylpropoxy)propyl, 2-(2-methylpropoxy)propyl, 2-(1,1-dimethylethoxy)propyl, 3-(methoxy)propyl, 3-(ethoxy)propyl, 3-(n-propoxy)propyl, 3-(1-methylethoxy)propyl, 3-(n-butoxy)propyl, 3-(1-methylpropoxy)propyl, 3-(2-methylpropoxy)propyl, 3-(1,1-dimethylethoxy)propyl, 2-(methoxy)butyl, 2-(ethoxy)butyl, 2-(n-propoxy)butyl, 2-(1-methylethoxy)butyl, 2-(n-butoxy)butyl, 2-(1-methylpropoxy)butyl, 2-(2-methylpropoxy)butyl, 2-(1,1-dimethylethoxy)butyl, 3-(methoxy)butyl, 3-(ethoxy)butyl, 3-(n-propoxy)butyl, 3-(1-methylethoxy)butyl, 3-(n-butoxy)butyl, 3-(1-methylpropoxy)butyl, 3-(2-methylpropoxy)butyl, 3-(1,1-dimethylethoxy)butyl, 4-(methoxy)butyl, 4-(ethoxy)butyl, 4-(n-propoxy)butyl, 4-(1-methylethoxy)butyl, 4-(n-butoxy)butyl, 4-(1-methylpropoxy)butyl, 4-(2-methylpropoxy)butyl, 4-(1,1-dimethylethoxy)butyl, and the like.

Alkylthio: alkyl as defined above preferably having 1 to 6 or 1 to 4 C atoms, which is linked via an S atom, e.g. methylthio, ethylthio, n-propylthio and the like.

Haloalkylthio: haloalkyl as defined above preferably having 1 to 6 or 1 to 4 C atoms, which is linked via an S atom, e.g. fluoromethylthio, difluoromethylthio, trifluoromethylthio, 2-fluoroethylthio, 2,2-difluoroethylthio, 2,2,2-trifluoroethylthio, pentafluoroethylthio, 2-fluoropropylthio, 3-fluoropropylthio, 2,2-difluoropropylthio, 2,3-difluoropropylthio, and heptafluoropropylthio.

Aryl: a mono-, bi- or tricyclic aromatic hydrocarbon radical such as phenyl or naphthyl, especially phenyl.

Heterocyclyl: a heterocyclic radical which may be saturated (“heterocycloalkyl”) or partly unsaturated and which ordinarily has 3, 4, 5, 6, 7 or 8 ring atoms, where ordinarily 1, 2, 3 or 4, in particular 1, 2 or 3, of the ring atoms are heteroatoms such as N, S or O, besides carbon atoms as ring members.

Examples of saturated heterocycles are in particular:

Heterocycloalkyl: i.e. a saturated heterocyclic radical which ordinarily has 3, 4, 5, 6 or 7 ring atoms, where ordinarily 1, 2 or 3 of the ring atoms are heteroatoms such as N, S or O, besides carbon atoms as ring members. These include for example:
C-bonded, 3-4-membered saturated rings such as
2-oxiranyl, 2-oxetanyl, 3-oxetanyl, 2-aziridinyl, 3-thiethanyl, 1-azetidinyl, 2-azetidinyl.
C-bonded, 5-membered saturated rings such as
tetrahydrofuran-2-yl, tetrahydrofuran-3-yl, tetrahydrothien-2-yl, tetrahydrothien-3-yl, tetrahydropyrrol-2-yl (pyrrolidine-2-yl), tetrahydropyrrol-3-yl (pyrrolidine-3-yl), tetrahydropyrazol-3-yl(pyrazolidine-3-yl), tetrahydropyrazol-4-yl (pyrazolidine-4-yl), tetrahydroisoxazol-3-yl (isoxazolidin-3-yl), tetrahydroisoxazol-4-yl (isoxazolidin-4-yl), tetrahydroisoxazol-5-yl (isoxazolidin-5-yl), 1,2-oxathiolan-3-yl, 1,2-oxathiolan-4-yl, 1,2-oxathiolan-5-yl, tetrahydroisothiazol-3-yl (isothiazolidin-3-yl), tetrahydroisothiazol-4-yl (isothiazolidin-4-yl), tetrahydroisothiazol-5-yl (isothiazolidin-5-yl), 1,2-dithiolan-3-yl, 1,2-dithiolan-4-yl, tetrahydroimidazol-2-yl (imidazolidin-2-yl), tetrahydroimidazol-4-yl (imidazolidin-4-yl), tetrahydrooxazol-2-yl (oxazolidin-2-yl), tetrahydrooxazol-4-yl (oxazolidin-4-yl), tetrahydrooxazol-5-yl (oxazolidin-5-yl), tetrahydrothiazol-2-yl (thiazolidin-2-yl), tetrahydrothiazol-4-yl (thiazolidin-4-yl), tetrahydrothiazol-5-yl (thiazolidin-5-yl), [1,2,3]triazolidin-4-yl, [1,2,4]triazolidin-3-yl, 1,3-dioxolan-2-yl, 1,3-dioxolan-4-yl, 1,3-oxathiolan-2-yl, 1,3-oxathiolan-4-yl, 1,3-oxathiolan-5-yl, 1,3-dithiolan-2-yl, 1,3-dithiolan-4-yl, 1,3,2-dioxathiolan-4-yl.
C-bonded, 6-membered saturated rings such as:
tetrahydropyran-2-yl, tetrahydropyran-3-yl, tetrahydropyran-4-yl, piperidin-2-yl, piperidin-3-yl, piperidin-4-yl, tetrahydrothiopyran-2-yl, tetrahydrothiopyran-3-yl, tetrahydrothiopyran-4-yl, 1,3-dioxan-2-yl, 1,3-dioxan-4-yl, 1,3-dioxan-5-yl, 1,4-dioxan-2-yl, 1,3-dithian-2-yl, 1,3-dithian-4-yl, 1,3-dithian-5-yl, 1,4-dithian-2-yl, 1,3-oxathian-2-yl, 1,3-oxathian-4-yl, 1,3-oxathian-5-yl, 1,3-oxathian-6-yl, 1,4-oxathian-2-yl, 1,4-oxathian-3-yl, 1,2-dithian-3-yl, 1,2-dithian-4-yl, hexahydropyrimidin-2-yl, hexahydropyrimidin-4-yl, hexahydropyrimidin-5-yl, piperazin-2-yl, hexahydropyridazin-3-yl, hexahydropyridazin-4-yl, tetrahydro-1,3-oxazin-2-yl, tetrahydro-1,3-oxazin-4-yl, tetrahydro-1,3-oxazin-5-yl, tetrahydro-1,3-oxazin-6-yl, tetrahydro-1,3-thiazin-2-yl, tetrahydro-1,3-thiazin-4-yl, tetrahydro-1,3-thiazin-5-yl, tetrahydro-1,3-thiazin-6-yl, tetrahydro-1,4-thiazin-2-yl, tetrahydro-1,4-thiazin-3-yl, morpholin-2-yl, morpholin-3-yl, tetrahydro-1,2-oxazin-3-yl, tetrahydro-1,2-oxazin-4-yl, tetrahydro-1,2-oxazin-5-yl, tetrahydro-1,2-oxazin-6-yl.
N-bonded, 5-membered saturated rings such as:
tetrahydropyrrol-1-yl(pyrrolidine-1-yl), tetrahydropyrazol-1-yl (pyrazolidin-1-yl), tetrahydroisoxazol-2-yl (isoxazolidin-2-yl), tetrahydroisothiazol-2-yl (isothiazolidin-2-yl), tetrahydroimidazol-1-yl(imidazolidin-1-yl), tetrahydrooxazol-3-yl (oxazolidin-3-yl), tetrahydrothiazol-3-yl (thiazolidin-3-yl).
N-bonded, 6-membered saturated rings such as:
piperidin-1-yl, hexahydropyrimidin-1-yl, hexahydropyrazin-1-yl(piperazin-1-yl), hexahydro-pyridazin-1-yl, tetrahydro-1,3-oxazin-3-yl, tetrahydro-1,3-thiazin-3-yl, tetrahydro-1,4-thiazin-4-yl, tetrahydro-1,4-oxazin-4-yl(morpholin-4-yl), tetrahydro-1,2-oxazin-2-yl.

Partially unsaturated heterocyclic radicals which ordinarily have 4, 5, 6 or 7 ring atoms, where ordinarily 1, 2 or 3 of the ring atoms are heteroatoms such as N, S or O, besides carbon atoms as ring members. These include for example:
C-bonded, 5-membered, partially unsaturated rings such as:
2,3-dihydrofuran-2-yl, 2,3-dihydrofuran-3-yl, 2,5-dihydrofuran-2-yl, 2,5-dihydrofuran-3-yl, 4,5-dihydrofuran-2-yl, 4,5-dihydrofuran-3-yl, 2,3-dihydrothien-2-yl, 2,3-dihydrothien-3-yl, 2,5-dihydrothien-2-yl, 2,5-dihydrothien-3-yl, 4,5-dihydrothien-2-yl, 4,5-dihydrothien-3-yl, 2,3-dihydro-1H-pyrrol-2-yl, 2,3-dihydro-1H-pyrrol-3-yl, 2,5-dihydro-1H-pyrrol-2-yl, 2,5-dihydro-1H-pyrrol-3-yl, 4,5-dihydro-1H-pyrrol-2-yl, 4,5-dihydro-1H-pyrrol-3-yl, 3,4-dihydro-2H-pyrrol-2-yl, 3,4-dihydro-2H-pyrrol-3-yl, 3,4-dihydro-5H-pyrrol-2-yl, 3,4-dihydro-5H-pyrrol-3-yl, 4,5-dihydro-1H-pyrazol-3-yl, 4,5-dihydro-1H-pyrazol-4-yl, 4,5-dihydro-1H-pyrazol-5-yl, 2,5-dihydro-1H-pyrazol-3-yl, 2,5-dihydro-1H-pyrazol-4-yl, 2,5-dihydro-1H-pyrazol-5-yl, 4,5-dihydroisoxazol-3-yl, 4,5-dihydroisoxazol-4-yl, 4,5-dihydroisoxazol-5-yl, 2,5-dihydroisoxazol-3-yl, 2,5-dihydroisoxazol-4-yl, 2,5-dihydroisoxazol-5-yl, 2,3-dihydroisoxazol-3-yl, 2,3-dihydroisoxazol-4-yl, 2,3-dihydroisoxazol-5-yl, 4,5-dihydroisothiazol-3-yl, 4,5-dihydroisothiazol-4-yl, 4,5-dihydroisothiazol-5-yl, 2,5-dihydroisothiazol-3-yl, 2,5-dihydroisothiazol-4-yl, 2,5-dihydroisothiazol-5-yl, 2,3-dihydroisothiazol-3-yl, 2,3-dihydroisothiazol-4-yl, 2,3-dihydroisothiazol-5-yl, 4,5-dihydro-1H-imidazol-2-yl, 4,5-dihydro-1H-imidazol-4-yl, 4,5-dihydro-1H-imidazol-5-yl, 2,5-dihydro-1H-imidazol-2-yl, 2,5-dihydro-1H-imidazol-4-yl, 2,5-dihydro-1H-imidazol-5-yl, 2,3-dihydro-1H-imidazol-2-yl, 2,3-dihydro-1H-imidazol-4-yl, 4,5-dihydrooxazol-2-yl, 4,5-dihydrooxazol-4-yl, 4,5-dihydrooxazol-5-yl, 2,5-dihydrooxazol-2-yl, 2,5-dihydrooxazol-4-yl, 2,5-dihydrooxazol-5-yl, 2,3-dihydrooxazol-2-yl, 2,3-dihydrooxazol-4-yl, 2,3-dihydrooxazol-5-yl, 4,5-dihydrothiazol-2-yl, 4,5-dihydrothiazol-4-yl, 4,5-dihydrothiazol-5-yl, 2,5-dihydrothiazol-2-yl, 2,5-dihydrothiazol-4-yl, 2,5-dihydrothiazol-5-yl, 2,3-dihydrothiazol-2-yl, 2,3-dihydrothiazol-4-yl, 2,3-dihydrothiazol-5-yl, 1,3-dioxol-2-yl, 1,3-dioxol-4-yl, 1,3-dithiol-2-yl, 1,3-dithiol-4-yl, 1,3-oxathiol-2-yl, 1,3-oxathiol-4-yl, 1,3-oxathiol-5-yl.
C-bonded, 6-membered, partially unsaturated rings such as:
2H-3,4-dihydropyran-6-yl, 2H-3,4-dihydropyran-5-yl, 2H-3,4-dihydropyran-4-yl, 2H-3,4-dihydropyran-3-yl, 2H-3,4-dihydropyran-2-yl, 2H-3,4-dihydrothiopyran-6-yl, 2H-3,4-dihydrothiopyran-5-yl, 2H-3,4-dihydrothiopyran-4-yl, 2H-3,4-dihydrothiopyran-3-yl, 2H-3,4-dihydrothiopyran-2-yl, 1,2,3,4-tetrahydropyridin-6-yl, 1,2,3,4-tetrahydropyridin-5-yl, 1,2,3,4-tetrahydropyridin-4-yl, 1,2,3,4-tetrahydropyridin-3-yl, 1,2,3,4-tetrahydropyridin-2-yl, 2H-5,6-dihydropyran-2-yl, 2H-5,6-dihydropyran-3-yl, 2H-5,6-dihydropyran-4-yl, 2H-5,6-dihydropyran-5-yl, 2H-5,6-dihydropyran-6-yl, 2H-5,6-dihydrothiopyran-2-yl, 2H-5,6-dihydrothiopyran-3-yl, 2H-5,6-dihydrothiopyran-4-yl, 2H-5,6-dihydrothiopyran-5-yl, 2H-5,6-dihydrothiopyran-6-yl, 1,2,5,6-tetrahydropyridin-2-yl, 1,2,5,6-tetrahydropyridin-3-yl, 1,2,5,6-tetrahydropyridin-4-yl, 1,2,5,6-tetrahydropyridin-5-yl, 1,2,5,6-tetrahydropyridin-6-yl, 2,3,4,5-tetrahydropyridin-2-yl, 2,3,4,5-tetrahydropyridin-3-yl, 2,3,4,5-tetrahydropyridin-4-yl, 2,3,4,5-tetrahydropyridin-5-yl, 2,3,4,5-tetrahydropyridin-6-yl, 4H-pyran-2-yl, 4H-pyran-3-yl, 4H-pyran-4-yl, 4H-thiopyran-2-yl, 4H-thiopyran-3-yl, 4H-thiopyran-4-yl, 1,4-dihydropyridin-2-yl, 1,4-dihydropyridin-3-yl, 1,4-dihydropyridin-4-yl, 2H-pyran-2-yl, 2H-pyran-3-yl, 2H-pyran-4-yl, 2H-pyran-5-yl, 2H-pyran-6-yl, 2H-thiopyran-2-yl, 2H-thiopyran-3-yl, 2H-thiopyran-4-yl, 2H-thiopyran-5-yl, 2H-thiopyran-6-yl, 1,2-dihydropyridin-2-yl, 1,2-dihydropyridin-3-yl, 1,2-dihydropyridin-4-yl, 1,2-dihydropyridin-5-yl, 1,2-dihydropyridin-6-yl, 3,4-dihydropyridin-2-yl, 3,4-dihydropyridin-3-yl, 3,4-dihydropyridin-4-yl, 3,4-dihydropyridin-5-yl, 3,4-dihydropyridin-6-yl, 2,5-dihydropyridin-2-yl, 2,5-dihydropyridin-3-yl, 2,5-dihydropyridin-4-yl, 2,5-dihydropyridin-5-yl, 2,5-dihydropyridin-6-yl, 2,3-dihydropyridin-2-yl, 2,3-dihydropyridin-3-yl, 2,3-dihydropyridin-4-yl, 2,3-dihydropyridin-5-yl, 2,3-dihydropyridin-6-yl, 2H-5,6-dihydro-1,2-oxazin-3-yl, 2H-5,6-dihydro-1,2-oxazin-4-yl, 2H-5,6-dihydro-1,2-oxazin-5-yl, 2H-5,6-dihydro-1,2-oxazin-6-yl, 2H-5,6-dihydro-1,2-thiazin-3-yl, 2H-5,6-dihydro-1,2-thiazin-4-yl, 2H-5,6-dihydro-1,2-thiazin-5-yl, 2H-5,6-dihydro-1,2-thiazin-6-yl, 4H-5,6-dihydro-1,2-oxazin-3-yl, 4H-5,6-dihydro-1,2-oxazin-4-yl, 4H-5,6-dihydro-1,2-oxazin-5-yl, 4H-5,6-dihydro-1,2-oxazin-6-yl, 4H-5,6-dihydro-1,2-thiazin-3-yl, 4H-5,6-dihydro-1,2-thiazin-4-yl, 4H-5,6-dihydro-1,2-thiazin-5-yl, 4H-5,6-dihydro-1,2-thiazin-6-yl, 2H-3,6-dihydro-1,2-oxazin-3-yl, 2H-3,6-dihydro-1,2-oxazin-4-yl, 2H-3,6-dihydro-1,2-oxazin-5-yl, 2H-3,6-dihydro-1,2-oxazin-6-yl, 2H-3,6-dihydro-1,2-thiazin-3-yl, 2H-3,6-dihydro-1,2-thiazin-4-yl, 2H-3,6-dihydro-1,2-thiazin-5-yl, 2H-3,6-dihydro-1,2-thiazin-6-yl, 2H-3,4-dihydro-1,2-oxazin-3-yl, 2H-3,4-dihydro-1,2-oxazin-4-yl, 2H-3,4-dihydro-1,2-oxazin-5-yl, 2H-3,4-dihydro-1,2-oxazin-6-yl, 2H-3,4-dihydro-1,2-thiazin-3-yl, 2H-3,4-dihydro-1,2-thiazin-4-yl, 2H-3,4-dihydro-1,2-thiazin-5-yl, 2H-3,4-dihydro-1,2-thiazin-6-yl, 2,3,4,5-tetrahydropyridazin-3-yl, 2,3,4,5-tetrahydropyridazin-4-yl, 2,3,4,5-tetrahydropyridazin-5-yl, 2,3,4,5-tetrahydropyridazin-6-yl, 3,4,5,6-tetrahydropyridazin-3-yl, 3,4,5,6-tetrahydropyridazin-4-yl, 1,2,5,6-tetrahydropyridazin-3-yl, 1,2,5,6-tetrahydropyridazin-4-yl, 1,2,5,6-tetrahydropyridazin-5-yl, 1,2,5,6-tetrahydropyridazin-6-yl, 1,2,3,6-tetrahydropyridazin-3-yl, 1,2,3,6-tetrahydropyridazin-4-yl, 4H-5,6-dihydro-1,3-oxazin-2-yl, 4H-5,6-dihydro-1,3-oxazin-4-yl, 4H-5,6-dihydro-1,3-oxazin-5-yl, 4H-5,6-dihydro-1,3-oxazin-6-yl, 4H-5,6-dihydro-1,3-thiazin-2-yl, 4H-5,6-dihydro-1,3-thiazin-4-yl, 4H-5,6-dihydro-1,3-thiazin-5-yl, 4H-5,6-dihydro-1,3-thiazin-6-yl, 3,4,5-6-tetrahydropyrimidin-2-yl, 3,4,5,6-tetrahydropyrimidin-4-yl, 3,4,5,6-tetrahydropyrimidin-5-yl, 3,4,5,6-tetrahydropyrimidin-6-yl, 1,2,3,4-tetrahydropyrazin-2-yl, 1,2,3,4-tetrahydropyrazin-5-yl, 1,2,3,4-tetrahydropyrimidin-2-yl, 1,2,3,4-tetrahydropyrimidin-4-yl, 1,2,3,4-tetrahydropyrimidin-5-yl, 1,2,3,4-tetrahydropyrimidin-6-yl, 2,3-dihydro-1,4-thiazin-2-yl, 2,3-dihydro-1,4-thiazin-3-yl, 2,3-dihydro-1,4-thiazin-5-yl, 2,3-dihydro-1,4-thiazin-6-yl, 2H-1,3-oxazin-2-yl, 2H-1,3-oxazin-4-yl, 2H-1,3-oxazin-5-yl, 2H-1,3-oxazin-6-yl, 2H-1,3-thiazin-2-yl, 2H-1,3-thiazin-4-yl, 2H-1,3-thiazin-5-yl, 2H-1,3-thiazin-6-yl, 4H-1,3-oxazin-2-yl, 4H-1,3-oxazin-4-yl, 4H-1,3-oxazin-5-yl, 4H-1,3-oxazin-6-yl, 4H-1,3-thiazin-2-yl, 4H-1,3-thiazin-4-yl, 4H-1,3-thiazin-5-yl, 4H-1,3-thiazin-6-yl, 6H-1,3-oxazin-2-yl, 6H-1,3-oxazin-4-yl, 6H-1,3-oxazin-5-yl, 6H-1,3-oxazin-6-yl, 6H-1,3-thiazin-2-yl, 6H-1,3-oxazin-4-yl, 6H-1,3-oxazin-5-yl, 6H-1,3-thiazin-6-yl, 2H-1,4-oxazin-2-yl, 2H-1,4-oxazin-3-yl, 2H-1,4-oxazin-5-yl, 2H-1,4-oxazin-6-yl, 2H-1,4-thiazin-2-yl, 2H-1,4-thiazin-3-yl, 2H-1,4-thiazin-5-yl, 2H-1,4-thiazin-6-yl, 4H-1,4-oxazin-2-yl, 4H-1,4-oxazin-3-yl, 4H-1,4-thiazin-2-yl, 4H-1,4-thiazin-3-yl, 1,4-dihydropyridazin-3-yl, 1,4-dihydropyridazin-4-yl, 1,4-dihydropyridazin-5-yl, 1,4-dihydropyridazin-6-yl, 1,4-dihydropyrazin-2-yl, 1,2-dihydropyrazin-2-yl, 1,2-dihydropyrazin-3-yl, 1,2-dihydropyrazin-5-yl, 1,2-dihydropyrazin-6-yl, 1,4-dihydropyrimidin-2-yl, 1,4-dihydropyrimidin-4-yl, 1,4-dihydropyrimidin-5-yl, 1,4-dihydropyrimidin-6-yl, 3,4-dihydropyrimidin-2-yl, 3,4-dihydropyrimidin-4-yl, 3,4-dihydropyrimidin-5-yl or 3,4-dihydropyrimidin-6-yl.
N-bonded, 5-membered, partially unsaturated rings such as:
2,3-dihydro-1H-pyrrol-1-yl, 2,5-dihydro-1H-pyrrol-1-yl, 4,5-dihydro-1H-pyrazol-1-yl, 2,5-dihydro-1H-pyrazol-1-yl, 2,3-dihydro-1H-pyrazol-1-yl, 2,5-dihydroisoxazol-2-yl, 2,3-dihydroisoxazol-2-yl, 2,5-dihydroisothiazol-2-yl, 2,3-dihydroisoxazol-2-yl, 4,5-dihydro-1H-imidazol-1-yl, 2,5-dihydro-1H-imidazol-1-yl, 2,3-dihydro-1H-imidazol-1-yl, 2,3-dihydrooxazol-3-yl, 2,3-dihydrothiazol-3-yl.
N-bonded, 6-membered, partially unsaturated rings such as:
1,2,3,4-tetrahydropyridin-1-yl, 1,2,5,6-tetrahydropyridin-1-yl, 1,4-dihydropyridin-1-yl, 1,2-dihydropyridin-1-yl, 2H-5,6-dihydro-1,2-oxazin-2-yl, 2H-5,6-dihydro-1,2-thiazin-2-yl, 2H-3,6-dihydro-1,2-oxazin-2-yl, 2H-3,6-dihydro-1,2-thiazin-2-yl, 2H-3,4-dihydro-1,2-oxazin-2-yl, 2H-3,4-dihydro-1,2-thiazin-2-yl, 2,3,4,5-tetrahydropyridazin-2-yl, 1,2,5,6-tetrahydropyridazin-1-yl, 1,2,5,6-tetrahydropyridazin-2-yl, 1,2,3,6-tetrahydropyridazin-1-yl, 3,4,5,6-tetrahydropyrimidin-3-yl, 1,2,3,4-tetrahydropyrazin-1-yl, 1,2,3,4-tetrahydropyrimidin-1-yl, 1,2,3,4-tetrahydropyrimidin-3-yl, 2,3-dihydro-1,4-thiazin-4-yl, 2H-1,2-oxazin-2-yl, 2H-1,2-thiazin-2-yl, 4H-1,4-oxazin-4-yl, 4H-1,4-thiazin-4-yl, 1,4-dihydropyridazin-1-yl, 1,4-dihydropyrazin-1-yl, 1,2-dihydropyrazin-1-yl, 1,4-dihydropyrimidin-1-yl or 3,4-dihydropyrimidin-3-yl.

Hetaryl: a 5- or 6-membered aromatic heterocyclic radical which ordinarily has 1, 2, 3 or 4 nitrogen atoms or a heteroatom selected from oxygen and sulfur and, if appropriate, 1, 2 or 3 nitrogen atoms as ring members besides carbon atoms as ring members: for example
C-bonded, 5-membered heteroaromatic radicals having 1, 2, 3 or 4 nitrogen atoms or a heteroatom selected from oxygen and sulfur and, if appropriate, having 1, 2 or 3 nitrogen atoms as ring members, such as:
2-furyl, 3-furyl, 2-thienyl, 3-thienyl, pyrrol-2-yl, pyrrol-3-yl, pyrazol-3-yl, pyrazol-4-yl, isoxazol-3-yl, isoxazol-4-yl, isoxazol-5-yl, isothiazol-3-yl, isothiazol-4-yl, isothiazol-5-yl, imidazol-2-yl, imidazol-4-yl, oxazol-2-yl, oxazol-4-yl, oxazol-5-yl, thiazol-2-yl, thiazol-4-yl, thiazol-5-yl, 1,2,3-oxadiazol-4-yl, 1,2,3-oxadiazol-5-yl, 1,2,4-oxadiazol-3-yl, 1,2,4,-oxadiazol-5-yl, 1,3,4-oxadiazol-2-yl, 1,2,3-thiadiazol-4-yl, 1,2,3-thiadiazol-5-yl, 1,2,4-thiadiazol-3-yl, 1,2,4-thiadiazol-5-yl, 1,3,4-thiadiazolyl-2-yl, 1,2,3-triazol-4-yl, 1,2,4-triazol-3-yl, tetrazol-5-yl.
C-bonded, 6-membered heteroaromatic radicals having 1, 2, 3 or 4 nitrogen atoms as ring members, such as:
pyridin-2-yl, pyridin-3-yl, pyridin-4-yl, pyridazin-3-yl, pyridazin-4-yl, pyrimidin-2-yl, pyrimidin-4-yl, pyrimidin-5-yl, pyrazin-2-yl, 1,3,5-triazin-2-yl, 1,2,4-triazin-3-yl, 1,2,4-triazin-5-yl, 1,2,4-triazin-6-yl, 1,2,4,5-tetrazin-3-yl.
N-bonded, 5-membered heteroaromatic radicals having 1, 2, 3 or 4 nitrogen atoms as ring members, such as:
pyrrol-1-yl, pyrazol-1-yl, imidazol-1-yl, 1,2,3-triazol-1-yl, 1,2,4-triazol-1-yl, tetrazol-1-yl.

Heterocyclyl also includes bicyclic heterocycles which have one of the aforementioned 5- or 6-membered heterocyclic rings and a further saturated, unsaturated or aromatic carbocycle fused thereto, for example a benzene, cyclohexane, cyclohexene or cyclohexadiene ring, or a further 5- or 6-membered heterocyclic ring fused thereto, where the latter may likewise be saturated, unsaturated or aromatic. These include for example quinolinyl, isoquinolinyl, indolyl, indolizynyl, isoindolyl, indazolyl, benzofuryl, benzothienyl, benzo[b]thiazolyl, benzoxazolyl, benzthiazolyl and benzimidazolyl. Examples of 5- to 6-membered heteroaromatic compounds comprising a fused benzene ring include dihydroindolyl, dihydroindolizynyl, dihydroisoindolyl, dihydroquinolinyl, dihydroisoquinolinyl, chromenyl and chromanyl.

Arylalkyl: an aryl radical as defined above which is linked via an alkylene group, in particular via a methylene, 1,1-ethylene or 1,2-ethylene group, e.g. benzyl, 1-phenylethyl and 2-phenylethyl.

Arylalkenyl: an aryl radical as defined above, which is linked via an alkenylene group, in particular via a 1,1-ethenyl, 1,2-ethenyl or 1,3-propenyl group, e.g. 2-phenylethen-1-yl and 1-phenylethen-1-yl.

Cycloalkoxy: a cycloalkyl radical as defined above which is linked via an oxygen atom, e.g. cyclopropyloxy, cyclobutyloxy, cyclopentyloxy or cyclohexyloxy.

Cycloalkylalkyl: a cycloalkyl radical as defined above which is linked via an alkylene group, in particular via a methylene, 1,1-ethylene or 1,2-ethylene group, e.g. cyclopropylmethyl, cyclobutylmethyl, cyclopentylmethyl or cyclohexylmethyl.

Heterocyclylalkyl and hetarylalkyl: a heterocyclyl or hetaryl radical as defined above which is linked via an alkylene group, in particular via a methylene, 1,1-ethylene or 1,2-ethylene group.

The expression “optionally substituted” means in the context of the present invention that the respective moiety is substituted or has 1, 2 or 3, in particular 1, substituents which are selected from halogen, C₁-C₄-alkyl, OH, SH, CN, CF₃, O—CF₃, COOH, O—CH₂—COOH, C₁-C₆-alkoxy, C₁-C₆-alkylthio, C₃-C₇-cycloalkyl, COO—C₁-C₆-alkyl, CONH₂, CONH—C₁-C₆-alkyl, SO₂NH—C₁-C₆-alkyl, CON—(C₁-C₆-alkyl)₂, SO₂N—(C₁-C₆-alkyl)₂, NH—SO₂—C₁-C₆-alkyl, NH—CO—C₁-C₆-alkyl, SO₂—C₁-C₆-alkyl, O-phenyl, O—CH₂-phenyl (benzoxy), CONH-phenyl, SO₂NH-phenyl, CONH-hetaryl, SO₂NH-hetaryl, SO₂-phenyl, NH—SO₂-phenyl, NH—CO-phenyl, NH—SO₂-hetaryl and NH—CO-hetaryl, where phenyl and hetaryl in the last 11 radicals mentioned are unsubstituted or may have 1, 2 or 3 substituents which are selected from halogen, C₁-C₄-alkyl, C₁-C₄-haloalkyl, C₁-C₄-alkoxy and C₁-C₄-haloalkoxy.

The remarks made below regarding preferred embodiments of the process and the device according to the invention, especially regarding preferred meanings of the variables of the different reactants and products and of the reaction conditions of the process, apply either taken alone or, more particularly, in any conceivable combination with one another.

Preferred hydroxamic acids and salts thereof (hydroxamates) are compounds of the general formula (I) (free acid) and of the general formula (I′) (salt)

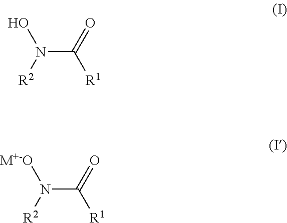

wherein
M⁺ is an alkali metal ion, an equivalent of an earth alkaline metal cation; or an NR′₄ cation, wherein R′ independently of each other are selected from hydrogen, C₁-C₆-alkyl, phenyl and benzyl, a pyridinium cation or an imidazolium cation, wherein the hetarylic moiety in the last two ions mentioned may be unsubstituted or substituted with 1, 2 or 3 substituents selected from C₁-C₄-alkyl and phenyl;
R¹ is C₁-C₁₈-alkyl, C₂-C₁₂-alkenyl, C₄-C₁₂-alkadienyl, C₆-C₁₂-alkatrienyl, C₂-C₁₂-alkynyl, where 1 to 4 CH₂ groups in the last 5 radicals mentioned may be replaced by O, NH, or S, and/or where the last 5 radicals mentioned may be partly or completely halogenated and/or have 1, 2 or 3 substituents R^{1a}, C₃-C₇-cycloalkyl, C₃-C₇-cycloalkyl-C₁-C₄-alkyl, C₃-C₇-heterocyclyl, C₃-C₇-heterocyclyl-C₁-C₄-alkyl, where cycloalkyl and heterocyclyl in the last 4 radicals mentioned may have 1, 2, 3 or 4 radicals R^{1b},
   aryl, hetaryl, aryl-C₁-C₆-alkyl, aryl-C₂-C₆-alkenyl, hetaryl-C₁-C₄-alkyl or hetaryl-C₂-C₆-alkenyl, where aryl and hetaryl in the last 6 radicals mentioned may be un-substituted or carry 1, 2, 3 or 4 identical or different radicals R^{1c}; where
   R^{1a} are selected independently of one another from OH, SH, NO₂, COOH, CHO, NR^{a1}R^{a2}, CN, OCH₂COOH, CO—NH—OH, CO—NH—O⁻ M⁺, C₁-C₁₂-alkoxy, C₁-C₁₂-halolkoxy, C₃-C₇-cycloalkyloxy, C₁-C₁₂-alkylthio, C₁-C₁₂-haloalkylthio, CO—C₁-C₁₂-alkyl, CO—O—C₁-C₁₂-alkyl, CONR^{a3}R^{a4}, aryl, hetaryl, aryl-C₁-C₆-alkoxy or hetaryl-C₁-C₄-alkoxy, where aryl and hetaryl in the last 4 radicals mentioned may be unsubstituted or carry 1, 2, 3 or 4 identical or different radicals R^{1c};
   R^{1b} are selected independently of one another from OH, SH, NO₂, COOH, CHO, NR^{b1}R^{b2}, CN, OCH₂COOH, halogen,
      aryl, aryl-C₁-C₆-alkyl, aryl-C₁-C₆-alkoxy, where aryl in the last 3 radicals mentioned may be unsubstituted or carry 1, 2, 3 or 4 identical or different radicals R^{1c};
      C₁-C₆-alkyl, C₁-C₆-alkoxy, C₁-C₆-alkylthio, where the alkyl moieties in the last 3 substituents mentioned may be partly or completely halogenated and/or have 1, 2 or 3 substituents R^{d1};
      CO—C₁-C₆-alkyl, CO—O—C₁-C₆-alkyl or CONR^{b3}R^{b4};
   R^{1c} are selected independently of one another from OH, SH, halogen, NO₂, NR^{c1}R^{c2}, CN, COOH, OCH₂COOH, C₁-C₁₂-alkyl, C₁-C₁₂-alkoxy, C₁-C₁₂-alkoxy-C₁-C₆-alkyl, C₁-C₁₂-alkylthio, where the alkyl moieties in the last 4 substituents mentioned may be partly or completely halogenated and/or have 1, 2 or 3 substituents R^{d1},
      C₃-C₇-cycloalkyl, C₃-C₇-cycloalkyl-C₁-C₄-alkyl, C₃-C₇-cycloalkyloxy, C₃-C₇-heterocyclyl, C₃-C₇-heterocyclyl-C₁-C₄-alkyl, C₃-C₇-heterocyclyloxy, where cycloalkyl and heterocyclyl in the last 6 radicals mentioned may have 1, 2, 3 or 4 radicals R^{d2},
      aryl, hetaryl, O-aryl, O—CH₂-aryl, where the last three radicals mentioned are unsubstituted in the aryl moiety or may carry 1, 2, 3 or 4 radicals R^{1d}, CO—C₁-C₆-alkyl, CO—O—C₁-C₆-alkyl, CONR^{c3}R^{c4},
      or two radicals R^{1b} or two radicals R^{1c} bonded to adjacent C atoms form together with the C atoms to which they are bonded a 4, 5, 6 or 7-membered, optionally substituted carbocycle or an optionally substituted heterocycle, which has 1, 2 or 3 different or identical heteroatoms from the group of O, N and S as ring members;
   R^{1d} are selected from halogen, OH, SH, NO₂, COOH, C(O)NH₂, CHO, CN, NH₂, OCH₂COOH, C₁-C₆-alkyl, C₁-C₆-haloalkyl, C₁-C₆-alkoxy, C₁-C₆-haloalkoxy, C₁-C₆-alkylthio, C₁-C₆-haloalkylthio, CO—C₁-C₆-alkyl, CO—O—C₁-C₆-alkyl, NH—C₁-C₆-alkyl, NHCHO, NH—C(O)C₁-C₆-alkyl, and SO₂—C₁-C₆-alkyl;
      R^{a1}, R^{b1} and R^{c1} are independently of one another H, C₁-C₆-alkyl, C₁-C₆-alkoxy, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, CO—C₁-C₆-alkyl, aryl, hetaryl, O-aryl, OCH₂-aryl, aryl-C₁-C₄-alkyl, hetaryl-C₁-C₄-alkyl, CO-aryl, CO-hetaryl, where aryl and hetaryl in the last 8 radicals mentioned are unsubstituted or have 1, 2 or 3 substituents R^{1d},
      R^{a2}, R^{b2} and R^{c2} are independently of one another H, C₁-C₆-alkyl, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, or
         the two radicals R^{a1} and R^{a2}, or R^{b1} and R^{b2} or R^{c1} and R^{c2} form together with the N atom a 3 to 7-membered, optionally substituted nitrogen heterocycle which may optionally have 1, 2 or 3 further different or identical heteroatoms from the group of O, N and S as ring members,
      R^{a1}, R^{b3} and R^{c3} are independently of one another H, C₁-C₆-alkyl, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, and
      R^{a4}, R^{b4} and R^{c4} are independently of one another H, C₁-C₆-alkyl, C₁-C₆-haloalkyl, C₁-C₆-alkyl which has 1, 2 or 3 substituents R^{b}', or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, or the two radicals R^{a3} and R^{a4}, or R^{b3}, and R^{b4} or R^{c3} and R^{c4} form together with the N atom a 3 to 7-membered, optionally substituted nitrogen heterocycle which may optionally have 1, 2 or 3 further different or identical heteroatoms from the group of O, N, S as ring members;
      R^{d}, are selected independently of one another from OH, SH, NO₂, COOH, CHO, NR^{a1}R^{a2}, CN, OCH₂COOH, C₁-C₁₂-alkoxy, C₁-C₁₂-halolkoxy, C₃-C₇-cycloalkyloxy, CO—C₁-C₁₂-alkyl, CO—O—C₁-C₁₂-alkyl, CONR^{a3}R^{a4}, aryl, hetaryl, aryl-C₁-C₆-alkoxy and hetaryl-C₁-C₄-alkoxy, where aryl and hetaryl in the last 4 radicals mentioned may be un-substituted or carry 1, 2, 3 or 4 identical or different radicals R^{1d};
      R^{d2} are selected independently of one another from OH, SH, NO₂, COOH, CHO, NR^{b1}R^{b2}, CN, OCH₂COOH, halogen, aryl, aryl-C₁-C₆-alkyl, aryl-C₁-C₆-alkoxy, where aryl in the last 3 radicals mentioned may be unsubstituted or carry 1, 2, 3 or 4 identical or different radicals R^{1d}, C₁-C₆-alkyl, C₁-C₆-alkoxy, C₁-C₆-alkylthio, where the alkyl moieties in the last 3 substituents mentioned may be partly or completely halogenated and/or have 1, 2 or 3 substituents R^{d1}; and
R² is H, C₁-C₆-alkyl, C₃-C₇-cycloalkyl or phenyl.

In case that R² is hydrogen, the structure of the hydroxamate salt may also be represent by following tautomer of formula I″:

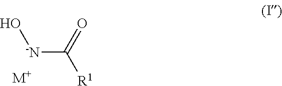

The actual structure of the hydroxamates is however not important for the present invention. Thus, in the following, the structure of formula I′ represents all possible structures of the hydroxamates.

In the compounds of the formula (I′) the ion M⁺ is preferably a lithium ion, sodium ion, potassium ion, caesium ion, rubidium ion, magnesium ion equivalent (½ Mg²⁺), calcium ion equivalent (½ Ca²⁺), or an NR′₄ ion, wherein R′ independently of each other are selected from hydrogen, C₁-C₆-alkyl, and benzyl, pyridinium ion or imidazolium ion. M⁺ is more preferably a lithium ion, a sodium ion, a potassium ion, a caesium ion, or an NR′₄ ion, wherein R′ independently of each other are selected from hydrogen and C₁-C₄-alkyl.

Even more preferably M⁺ is a lithium ion, a sodium ion, a potassium ion, a caesium ion, or an N(n-butyl)₄ ion.

In the radicals R¹ of the compounds I and I′, the radicals R^{1a}, where present, are preferably selected independently of one another from NO₂, CN, CO—NH—OH, CO—NH—O⁻ M⁺, C₁-C₁₂-alkoxy, C₁-C₁₂-halolkoxy, aryl, hetaryl, aryl-C₁-C₆-alkoxy and hetaryl-C₁-C₄-alkoxy, where aryl and hetaryl in the last 4 radicals mentioned may be unsubstituted or carry 1, 2 or 3 identical or different radicals R^{1c}.

More preferably the radicals R^{1a}, where present, are selected independently of one another from CO—NH—OH, CO—NH—O⁻ M⁺, C₁-C₆-alkoxy, phenyl and phenyl-C₁-C₆-alkoxy, where phenyl in the last 2 radicals mentioned may be unsubstituted or carry 1, 2 or 3 identical or different radicals R^{1c}.

Even more preferably R^{1a}, where present, are selected independently of one another from CO—NH—OH, CO—NH—O⁻ M⁺, phenyl and phenyl-C₁-C₃-alkoxy, where phenyl in the last 2 radicals mentioned may be unsubstituted or carry 1 or 2 identical or different radicals selected from C₃-C₁₂-alkyl, C₃-C₁₂-alkoxy and benzoxy (benzyloxy).

Specifically, R^{1a}, where present, are selected independently of one another from CO—NH—OH, CO—NH—O⁻ M⁺ and phenyl, where phenyl may be unsubstituted or carry 1 or 2, preferably 1, identical or different radicals selected from C₃-C₁₂-alkoxy and benzoxy (benzyloxy). If phenyl carries 1 radical, this is preferably bound in para-position, i.e. in 4-position relative to the 1-position via which the phenyl ring is bound to the radical R¹.

In the radicals R¹ of the compounds I and I′, the radicals R^{1b}, where present, are preferably selected independently of one another from NO₂, CN, halogen, aryl, aryl-C₁-C₆-alkyl, aryl-C₁-C₆-alkoxy, where aryl in the last 3 radicals mentioned may be unsubstituted or carry 1, 2 or 3 identical or different radicals R^{1c}, C₁-C₆-alkyl and C₁-C₆-alkoxy, where the alkyl moieties in the last 2 substituents mentioned may be partly or completely halogenated and/or have 1 or 2 substituents R^{d1}.

More preferably the radicals R^{1b}, where present, are selected independently of one another from halogen, phenyl, phenyl-C₁-C₆-alkyl, phenyl-C₁-C₆-alkoxy, where phenyl in the last 3 radicals mentioned may be unsubstituted or carry 1 or 2 identical or different radicals selected from C₁-C₁₂-alkyl, C₁-C₁₂-alkoxy and O—CH₂-aryl, C₁-C₆-alkyl and C₁-C₆-alkoxy, where the alkyl moieties in the last 2 substituents mentioned may be partly or completely halogenated and/or have 1 or 2 substituents R^{d1}.

Even more preferably R^{1b}, where present, are selected independently of one another from phenyl, phenyl-C₁-C₃-alkyl, phenyl-C₁-C₃-alkoxy, where phenyl in the last 3 radicals mentioned may be unsubstituted or carry a radical selected from C₃-C₁₂-alkyl, C₃-C₁₂-alkoxy and benzoxy, C₁-C₆-alkyl and C₁-C₆-alkoxy, where the alkyl moieties in the last 2 substituents mentioned may be unsubstituted or carry a radical selected from C₃-C₁₂-alkoxy and benzoxy.

In the radicals R¹, R^{1a} and R^{1b} of the compounds I and I′, the radicals R^{1c}, where present, are preferably selected independently of one another from halogen, NO₂, CN, C₁-C₁₂-alkyl, C₁-C₁₂-alkoxy, C₁-C₁₂-alkoxy-C₁-C₄-alkyl, where the alkyl moieties in the last 3 substituents mentioned may be partly or completely halogenated and/or have 1 or 2 substituents R^{d1}, C₃-C₇-cycloalkyl, C₃-C₇-cycloalkyl-C₁-C₄-alkyl, C₃-C₆-heterocyclyl, C₃-C₆-heterocyclyl-C₁-C₄-alkyl, where cycloalkyl and heterocyclyl in the last 4 radicals mentioned may have 1, 2 or 3 R^{d2} radicals, aryl, O-aryl and O—CH₂-aryl, where the last three radicals mentioned are unsubstituted in the aryl moiety or may carry 1, 2 or 3 radicals independently of one another selected from halogen, NO₂, CN, NH₂, C₁-C₆-alkyl, C₁-C₆-haloalkyl, C₁-C₆-alkoxy and C₁-C₆-haloalkoxy.

More preferably R^{1c}, where present, are selected independently of one another from halogen, C₁-C₁₂-alkyl, C₁-C₁₂-alkoxy, where the alkyl moieties in the last 2 substituents mentioned may be partly or completely halogenated and/or have a substituent R^{d1}, C₃-C₇-cycloalkyl, C₃-C₇-cycloalkyl-C₁-C₄-alkyl, where the cycloalkyl moiety of the last 2 radicals mentioned may have a substituent R^{d2}, aryl and O—CH₂-aryl, where the last two radicals mentioned are unsubstituted in the aryl moiety or may carry 1 or 2 radicals independently of one another selected from halogen, NO₂, C₁-C₆-alkyl, C₁-C₆-haloalkyl and C₁-C₆-alkoxy.

Even more preferably R^{1c}, where present, are selected independently of one another from halogen, C₁-C₁₂-alkyl, C₁-C₁₂-alkoxy, where the alkyl moieties in the last 2 substituents mentioned may be partly or completely halogenated and/or have a substituent selected from C₃-C₁₂-alkoxy, phenyl and benzoxy, C₃-C₇-cycloalkyl, C₃-C₇-cycloalkyl-C₁-C₄-alkyl, where the cycloalkyl moiety of the last 2 radicals mentioned may have a substituent selected from phenyl, phenyl-C₁-C₃-alkyl, benzoxy, C₁-C₆-alkyl and C₁-C₆-alkoxy, aryl and O—CH₂-aryl, where the last two radicals mentioned are unsubstituted in the aryl moiety or may carry a substituent selected from halogen, C₁-C₆-alkyl, C₁-C₆-haloalkyl and C₁-C₆-alkoxy.

Specifically, R^{1c}, where present, are selected independently of one another from C₁-C₁₂-alkoxy and O—CH₂-aryl and more specifically from C₃-C₁₂-alkoxy and benzoxy (benzyloxy).

In the radicals R^{1b} and R^{1c} of the compounds I and I′, the radicals R^{d1}, where present, are preferably selected independently of one another from OH, NO₂, COOH, CN, C₁-C₁₂-alkoxy, C₁-C₁₂-halolkoxy, CO—C₁-C₁₂-alkyl, CO—O—C₁-C₁₂-alkyl, aryl and aryl-C₁-C₆-alkoxy, where aryl in the last 2 radicals mentioned may be unsubstituted or may carry 1, 2 or 3 radicals independently of one another selected from halogen, NO₂, CN, NH₂, C₁-C₆-alkyl, C₁-C₆-haloalkyl, C₁-C₆-alkoxy and C₁-C₆-haloalkoxy.

More preferably R^{d1}, where present, are selected independently of one another from NO₂, CN, C₁-C₁₂-alkoxy, C₁-C₁₂-halolkoxy, aryl and aryl-C₁-C₆-alkoxy, where aryl in the last 2 radicals mentioned may be unsubstituted or may carry 1 or 2 radicals independently of one another selected from halogen, NO₂, CN, C₁-C₆-alkyl, C₁-C₆-haloalkyl, C₁-C₆-alkoxy and C₁-C₆-haloalkoxy.

Even more preferably R^{d1}, where present, are selected independently of one another from C₁-C₁₂-alkoxy, phenyl and benzoxy, where phenyl in the last 2 radicals mentioned may be unsubstituted or may carry 1 or 2 radicals independently of one another selected from halogen, C₁-C₆-alkyl, C₁-C₆-haloalkyl and C₁-C₆-alkoxy.

In the radicals R^{1b} and R^{1c} of the compounds I and I′, the radicals R^{d2}, where present, are preferably selected independently of one another from OH, NO₂, COOH, CN, halogen, aryl, aryl-C₁-C₆-alkyl, aryl-C₁-C₆-alkoxy, where aryl in the last 3 radicals mentioned may be unsubstituted or carry 1, 2 or 3 radicals independently of one another selected from halogen, NO₂, CN, NH₂, C₁-C₆-alkyl, C₁-C₆-haloalkyl, C₁-C₆-alkoxy and C₁-C₆-haloalkoxy, C₁-C₆-alkyl and C₁-C₆-alkoxy, where the alkyl moieties in the last 2 substituents mentioned may be partly or completely halogenated and/or have 1, 2 or 3 substituents independently of one another selected from C₁-C₁₂-alkoxy, aryl and aryl-C₁-C₆-alkoxy.

More preferably R^{d2}, where present, are selected independently of one another from NO₂, CN, halogen, aryl, aryl-C₁-C₆-alkyl, aryl-C₁-C₆-alkoxy, where aryl in the last 3 radicals mentioned may be unsubstituted or carry 1 or 2 radicals independently of one another selected from halogen, C₁-C₆-alkyl, C₁-C₆-haloalkyl, C₁-C₆-alkoxy and C₁-C₆-haloalkoxy, C₁-C₆-alkyl and C₁-C₆-alkoxy, where the alkyl moieties in the last 2 substituents mentioned may be partly or completely halogenated and/or have 1 or 2 substituents independently of one another selected from C₁-C₁₂-alkoxy, aryl and aryl-C₁-C₆-alkoxy.

Even more preferably R^{d2}, where present, are selected independently of one another from halogen, phenyl, benzyl, benzoxy, where phenyl in the last 3 radicals mentioned may be unsubstituted or carry 1 or 2 radicals independently of one another selected from halogen, C₁-C₆-alkyl, C₁-C₆-haloalkyl and C₁-C₆-alkoxy, C₁-C₆-alkyl and C₁-C₆-alkoxy, where the alkyl moieties in the last 2 substituents mentioned may be partly or completely halogenated and/or have 1 or 2 substituents independently of one another selected from C₃-C₁₂-alkoxy, phenyl and benzoxy.

In the compounds of the formulae (I) and (I′) the radical R¹ is preferably C₁-C₁₀-alkyl, C₂-C₁₀-alkenyl, C₄-C₁₀-alkadienyl, where the last 3 radicals mentioned may be partly or completely halogenated and/or have 1, 2 or 3 substituents R^{1a}, where R^{1a} has one of the above-given general or, in particular, one of the above-given preferred meanings;

C₃-C₇-cycloalkyl, C₃-C₇-cycloalkyl-C₁-C₄-alkyl, C₃-C₇-heterocyclyl, C₃-C₇-heterocyclyl-C₁-C₄-alkyl, where cycloalkyl and heterocyclyl in the last 4 radicals mentioned may have 1, 2 or 3 radicals R^{1b}, where R^{1b} has one of the above-given general or, in particular, one of the above-given preferred meanings;

aryl, hetaryl, aryl-C₁-C₆-alkyl or hetaryl-C₁-C₄-alkyl, where aryl and hetaryl in the last 4 radicals mentioned may be unsubstituted or carry 1, 2 or 3 identical or different radicals R^{1c}, where R^{1c} has one of the above-given general or, in particular, one of the above-given preferred meanings.

R¹ is more preferably C₁-C₁₀-alkyl, C₂-C₁₀-alkenyl or C₄-C₁₀-alkadienyl, where the last 3 radicals mentioned may be unsubstituted or substituted with 1, 2 or 3 substituents independently of one another selected from CO—NH—OH, CO—NH—O⁻ M⁺, C₁-C₆-alkoxy, phenyl and phenyl-C₁-C₆-alkoxy, where phenyl in the last 2 radicals mentioned may be unsubstituted or substituted with 1, 2 or 3 substituents independently of one another selected from C₃-C₁₂-alkyl, C₃-C₁₂-alkoxy, C₃-C₁₂-alkoxy-C₁-C₄-alkyl and phenyl-C₁-C₆-alkoxy.

Even more preferably R¹ is C₁-C₁₀-alkyl, C₂-C₁₀-alkenyl or C₄-C₁₀-alkadienyl, where the last 3 radicals mentioned may be unsubstituted or substituted with 1, 2 or 3 substituents independently of one another selected from CO—NH—OH, CO—NH—O⁻ M⁺, C₁-C₆-alkoxy, phenyl and phenyl-C₁-C₆-alkoxy, where phenyl in the last 2 radicals mentioned may be unsubstituted or substituted with 1 or 2 substituents independently of one another selected from C₃-C₁₂-alkyl, C₃-C₁₂-alkoxy and benzoxy (benzyloxy).

Particularly preferably R¹ is C₁-C₁₀-alkyl or C₄-C₁₀-alkadienyl, where the last 2 radicals mentioned may be unsubstituted or substituted with 1 substituent selected from CO—NH—OH, CO—NH—O⁻ M⁺ and phenyl, which may be unsubstituted or substituted with C₃-C₁₂-alkoxy or benzoxy.

In particular, R¹ is C₃-C₁₀-alkyl which is unsubstituted or carries a group CO—NH—OH, CO—NH—O⁻ M⁺, or is C₄-C₁₀-alkadienyl or is benzyl which carries one substituent selected from C₃-C₁₂-alkoxy and benzyloxy and preferably from C₃-C₆-alkoxy and benzyloxy. Preferably, benzyl carries the substituent in para-position (4-position), i.e. in 4-position relative to the 1-position in which the phenyl ring of the benzyl moiety is bound to the CH₂ group of the benzyl moiety.

In the compounds of the formulae (I) and (I′) the radical R² is preferably hydrogen, C₁-C₄-alkyl, cyclohexyl or phenyl.

R² is more preferably hydrogen or methyl.

Even more preferably R² is hydrogen.

The hydroxamic acids used according to the invention are generally commercially available or can be prepared in accordance with methods known in the art. The hydroxamate salts are also either commercially available or can be prepared from the corresponding hydroxamic acids by known methods, e.g. by reacting the hydroxamic acids with a base, such as an alkali metal or earth alkaline metal hydroxide, such as lithium hydroxide, sodium hydroxide, potassium hydroxide, caesium hydroxide, rubidium hydroxide, magnesium hydroxide or calcium hydroxide, alkali metal or earth alkaline metal carbonate, such as lithium carbonate, sodium carbonate, potassium carbonate, magnesium carbonate or calcium carbonate, ammonia, an amine, such as methylamine, dimethylamine, trimethylamine, ethylamine, diethylamine, triethylamine, propylamine, dipropylamine, tripropylamine, butylamine, dibutylamine, tributylamine, ethanolamine, diethanolamine, triethanolamine and the like.

In the process for producing a dye-sensitized photoelectric conversion device of the present invention, the semi-conductive metal oxide is treated with at least one hydroxamic acid or its salt which is essentially transparent in the electromagnetic wavelength range of 400 to 1000 nm and preferably 400 to 800 nm. Thus, the at least one hydroxamic acid or a salt thereof does not or only to a minor extent absorb the radiation of the sun in the stated wavelength intervals. It is therefore clearly distinguished from chromophoric substances suitable for sensitizing the semi-conductive metal oxide, which have much higher extinction coefficients in the stated wavelength ranges exceeding 10³ L·mol⁻¹·cm⁻¹ and being typically in the range of 15,000 to 150,000 L·mol⁻¹·cm⁻¹ and more typically in a range of from 20,000 to 80,000 L·mol⁻¹·cm⁻¹. The at least one hydroxamic acid or its salt according to the invention is preferably a compound of the general formula (I) or formula (I′), respectively, in particular one mentioned herein as preferred.

The term “the semi-conductive metal oxide is treated with at least one hydroxamic acid or a salt thereof” means that the semi-conductive metal oxide is made to come into contact with one or more hydroxamic acids or their salts for a predetermined period before the next step in the production of the photoelectric conversion device is carried out; e.g. before a charge transfer layer, as described in more detail below, is applied. Without wishing to be bound by theory, it is supposed that after the treatment, the semi-conductive metal oxide comprises the at least one hydroxamic acid or its salt, in an absorbed form, supposedly in an amount that, in general, is less than the amount employed.

Although the semi-conductive metal oxide may be treated with one or more hydroxamic acids or their salts at any stage during production of the photoelectric conversion device, it is preferably treated with the one or more hydroxamic acids or their salts after a layer of semi-conductive metal oxide is provided, preferably either after blocking the layer deposition (see below) or, more preferably, simply after deposition of the semiconductive metal oxide layer. The remarks made below apply however both to the treatment of the semi-conductive metal oxide in any form as well as to the treatment of the semi-conductive metal oxide in form of a semi-conductive metal oxide layer. Preferably, they apply to the treatment of a semi-conductive metal oxide layer.

It is preferred that the semi-conductive metal oxide is treated with a solution prepared by dissolving the one or more hydroxamic acids or their salt in a solvent, hereinafter referred to as “treatment solution”, or with a dispersion prepared by dispersing the one or more hydroxamic acids or their salts in a solvent, hereinafter referred to as “treatment dispersion”. If the at least one hydroxamic acid or its salt is liquid, it also may be used without a solvent. However it is preferred that the semi-conductive metal oxide is treated with the treatment solution or dispersion and more preferably with the treatment solution.

In case the semi-conductive metal oxide is treated with more than one hydroxamic acid or its salt, it may be treated successively with more than one treatment solution or treatment dispersion, each of which containing less than the total number of hydroxamic acids or their salts intended for treatment. Preferably, however, the semiconductive metal oxide is treated with one treatment solution or one treatment dispersion containing all hydroxamic acids or their salts that are intended for treatment.

The solvent used for the treatment solution or the treatment dispersion is preferably an organic solvent. The organic solvent may be properly selected depending on the solubility of the one or more hydroxamic acids or their salts. Examples of the organic solvent include: alcohol solvents such as methanol, ethanol, propanol, isopropanol, n-butanol, t-butanol, ethylene glycol and benzylalcohol; nitrile solvents such as acetonitrile, propionitrile and 3-methoxypropionitrile; nitromethane; halogenated hydrocarbons such as dichloromethane, dichloroethane, chloroform and chlorobenzene; ether solvents such as diethylether, methyl tert-butyl ether, methyl isobutyl ether, dioxan and tetrahydrofuran; dimethylsulfoxide; amide solvents such as N,N-dimethylformamide and N,N-dimethylacetamide; N-methylpyrrolidone; 1,3-dimethylimidazolidinone; 3-methyloxazolidinone; ester solvents such as ethyl acetate, propyl acetate, ethyl propionate and butylacetate; carbonate solvents such as diethyl carbonate, ethylene carbonate and propylene carbonate; ketone solvents such as acetone, 2-butanone and cyclohexanone; hydrocarbon solvents such as hexane, petroleum ether, cyclohexane, benzene and toluene; and mixtures thereof. Among them, particularly preferred are the above alcohol solvents, nitrile solvents and amide solvents.

The semi-conductive metal oxide may be treated with the at least one hydroxamic acid or its salt by:
(a) a method where it is treated with the at least one hydroxamic acid or its salt after the dye is adsorbed thereon, hereinafter referred to as “post-treatment method”;
(b) a method where it is treated with the at least one hydroxamic acid or its salt while the dye is adsorbed thereon, hereinafter referred to as “simultaneous treatment method”; or
(c) a method where it is treated with the at least one hydroxamic acid or its salt before the dye is adsorbed thereon, hereinafter referred to as “pre-treatment method.”

Of these methods, preferred are the post-treatment method and the pre-treatment method and particularly preferred is the pre-treatment method.

Alternatively, these methods may be used in combination with each other. This means that the semi-conductive metal oxide may be successively or stepwise treated with one or more hydroxamic acids or their salts a plurality of times. For example, a two step treatment method comprising the pre-treatment method and the simultaneous treatment method may be used. In the case where a plurality of treatments with one or more hydroxamic acids or their salts are carried out, the one or more hydroxamic acids or their salts used for each treatment may be the same or different.

In the case of using the treatment solution or the treatment dispersion, wherein both of them are hereinafter referred to as “treatment liquid”, the semi-conductive metal oxide may be treated with the treatment liquid by different methods, such as dipping, soaking, spraying, coating or flushing/rinsing. Preferably the semi-conductive metal oxide is treated with the treatment liquid by a dipping or soaking treatment method where the semi-conductive metal oxide is dipped or soaked in the treatment liquid. Further, the semi-conductive metal oxide may be treated with the treatment liquid by a spraying treatment method where the treatment liquid is sprayed on the semi-conductive metal oxide in the pre-treatment method or the post-treatment method.

In the dipping or soaking treatment method, although the temperature of the treatment liquid and the treatment period may be varied within a broad range, it is preferable that the treatment is carried out with the liquid having a temperature of from 0 to 100° C., preferably from 15 to 80° C., preferably for 1 second to 24 hours, more preferably for 1 second to 3 hours.

After the treatment, especially the dipping or soaking treatment, the semi-conductive metal oxide is preferably washed with a solvent. The solvent is preferably the same as that used for the treatment liquid, and is more preferably a polar solvent such as e.g. a nitrile solvent, an alcohol solvent or an amide solvent, as those mentioned above.

The concentration of the at least one hydroxamic acid or its salt in the treating liquid (I) is preferably from 1·10⁻⁶ to 2 mol/L, more preferably from 1·10⁻⁵ to 1 mol/L, in particular from 1·10⁻⁴ to 5·10⁻¹ mol/L and specifically from 5·10⁻⁴ to 1·10⁻² mol/L.

Dye-sensitized photoelectric conversion devices generally comprise following elements: an electrically conductive layer (being part of or forming the working electrode or anode), a photosensitive layer generally comprising a semi-conductive metal oxide and a photosensitive dye, a charge transfer layer and another electrically conductive layer (being part of or forming the counter electrode or cathode).

Thus, the photoelectric conversion device of the present invention preferably comprises the following elements, as described in more detail below: an electrically conductive layer; a photosensitive layer containing semi-conductive metal oxides sensitized by dyes (chromophoric substances) and treated with one or more hydroxamic acids or salts thereof; a charge transfer layer; and a counter electrically conductive layer, typically processed in this order. An undercoating layer may be disposed between the electrically conductive layer and the photosensitive layer.

“Layer” in this context does not necessarily imply that each layer is physically strictly separated from the other layers. In fact, the layers may permeate into each other. For instance, the material of which the charge transfer layer is composed generally permeates into the photosensitive layer and comes into close contact with the semiconductive metal oxide and the dye, so that a fast charge transfer is possible.

Accordingly, the invention also pertains to a process for producing a dye-sensitized photoelectric conversion device comprising the following steps:
i) providing an electrically conductive layer;
ii) optionally depositing an undercoating layer thereon, iii) depositing a photosensitive layer on the electrically conductive layer obtained in step i) or, if present, the undercoating layer obtained in step ii), wherein the photosensitive layer contains a semi-conductive metal oxide sensitized by a chromophoric substance and treated with at least one hydroxamic acid or at least one salt thereof;
iv) depositing a charge transfer layer on the photosensitive layer obtained in step iii); and
v) depositing a counter electrically conductive layer on the charge transfer layer obtained in step iv).

The electrically conductive layer and/or the counter electrically conductive layer may be disposed on a substrate (also called support or carrier) to improve the strength of the photoelectric conversion device. In the present invention, a layer composed of the electrically conductive layer and a substrate on which it is disposed is referred to as conductive support. A layer composed of the counter electrically conductive layer and a substrate on which it is optionally disposed is referred to as counter electrode. Preferably, the electrically conductive layer and the substrate on which it is optionally disposed are transparent. The counter electrically conductive layer and optionally also the support on which this is optionally disposed may be transparent too, but this is not critical.

Each layer comprised in the photoelectric conversion device obtained in the method of the present invention will be explained in detail below.

(A) Electrically Conductive Layer [Step (i)]

The electrically conductive layer is either as such stable enough to support the remaining layers, or the electrically conductive material forming the electrically conductive layer is disposed on a substrate (also called support or carrier). Preferably, the electrically conductive material forming the electrically conductive layer is disposed on a substrate. The combination of electrically conductive material disposed on a substrate is called in the following “conductive support”.

In the first case, the electrically conductive layer is preferably made of a material that has a sufficient strength and that can sufficiently seal the photoelectric conversion device, for example, a metal such as platinum, gold, silver, copper, zinc, titanium, aluminum and an alloy composed thereof.

In the second case, the substrate on which the electrically conductive layer containing an electrically conductive material is generally disposed opposite of the photosensitive layer, so that the electrically conductive layer is in direct contact with the photosensitive layer.

Preferred examples of the electrically conductive material include: metals such as platinum, gold, silver, copper, zinc, titanium, aluminum, indium and alloys composed thereof; carbon, especially in the form of carbon nano tubes; and electrically conductive metal oxides, especially transparent conductive oxides (TCO), such as for example indium-tin composite oxides, tin oxides doped with fluorine, antimony or indium and zinc oxide doped with aluminum. In case of metals, these are generally used in form of thin films, so that they form a sufficiently transparent layer. More preferably, the electrically conductive material is selected from transparent conductive oxides (TOO). Among these, tin oxides doped with fluorine, antimony or indium and indium-tin oxide (ITO) are preferred, more preferred being tin oxides doped with fluorine, antimony or indium and specifically preferred being tin oxides doped with fluorine. Specifically, the tin oxide is SnO₂.

The electrically conductive layer preferably has a thickness of 0.02 to 10 μM and more preferably from 0.1 to 1 μm.

Generally, light will be irradiated from the side of the electrically conductive layer (and not from the counter electrically conductive layer side). Thus, as already mentioned, it is preferred that the support which carries the electrically conductive layer and preferably the conductive support as a whole is substantially transparent. Herein, the term “substantially transparent” means that the light transmittance is 50% or more to a light in visible region to near infrared region (400 to 1000 nm). The light transmittance is preferably 60% or more, more preferably 70% or more and in particular 80% or more. The conductive support particularly preferably has high light transmittance to a light that the photosensitive layer has sensitivity to.

The substrate may be made of a glass such as low-cost soda glass excellent in strength and non-alkali glass that is not affected by alkaline elution. Alternatively, a transparent polymer film may be used as substrate. Used as the materials for the polymer film may be tetraacetyl cellulose (TAC), polyethylene terephthalate (PET), polyethylene naphthalate (PEN), syndiotactic polystyrene (SPS), polyphenylenesulfide (PPS), polycarbonate (PC), polyarylate (PAr), polysulfone (PSF), polyestersulfone (PES), polyimide (PI), polyetherimide (PEI), cyclic polyolefin, brominated phenoxy resin, and the like.

The conductive support is preferably prepared by disposing the electrically conductive material on the substrate by means of for example coating or vapor deposition.

The amount of the electrically conductive material to be disposed on the substrate is chosen so that a sufficient transparency is secured. The suitable amount depends on the conductive material and the substrate used and will be determined for the single cases. For instance, in case of TCOs as conductive material and glass as substrate the amount may vary from 0.01 to 100 g per 1 m².

It is preferable that a metal lead is used to reduce the resistance of the conductive support. The metal lead is preferably made of a metal such as platinum, gold, nickel, titanium, aluminum, copper, silver, etc. It is preferable that the metal lead is provided on the substrate by a vapor deposition method, a sputtering method or the like, the electrically conductive layer being disposed thereon. The reduction in incident light quantity owing to the metal lead is limited to preferably 10% or less, more preferably 1 to 5% or less.

(B) Undercoating Layer (“Buffering Layer”) [Optional Step (ii)]

The layer obtained in step (i) may be coated with a buffering layer. The purpose is to avoid a direct contact of the charge transfer layer with the electrically conductive layer and thus to prevent short-circuits, particularly in the case where the charge transfer layer is a solid hole-transporting material.

This “undercoating” or buffering layer material is preferably a metal oxide. The metal oxide is preferably selected from a titanium, tin, zinc, iron, tungsten, vanadium or niobium oxide, such as TiO₂, SnO₂, Fe₂O₃, WO₃, ZnO, V₂O₅ or Nb₂O₅, and is more preferably TiO₂.

The undercoating layer may be disposed e.g. by a spray-pyrolysis method as described for example in Electrochim. Acta, 40, 643 to 652 (1995), or a sputtering method as described for example in Thin Solid Films 445, 251-258 (2003), Suf. Coat. Technol. 200, 967 to 971 (2005) or Coord. Chem. Rev. 248 (2004), 1479.

The thickness of the undercoating layer is preferably 5 to 1000 nm, more preferably 10 to 500 nm and in particular 10 to 200 nm.

In the case of liquid electrolytes based on I⁻/I₃⁻ as charge transfer layer material, the risk of short-circuit is rather low and thus the undercoating layer is principally superfluous and can be dispensed with. The absence of this optional layer in such cells can enhance the efficiency of the photoelectric conversion device as the undercoating layer has a current-reducing effect and may also impair the contact between the photosensitive layer and the electrically conductive layer. On the other side, however, the undercoating layer helps avoiding problems with undesired charge recombination processes, so that its application is connected with advantages especially in case of solid charge transfer layers.

(C) Photosensitive Layer [Step (iii)]

The photosensitive layer contains the semi-conductive metal oxide sensitized with a chromophoric substance (also called dye or photosensitive dye). The dye-sensitized semi-conductive metal oxide acts as a photosensitive substance to absorb light and conduct charge separation, thereby generating electrons. As is generally known, thin layers or films of metal oxides are useful solid semi-conductive materials (n-semiconductors). However, due to their large band gap they don't absorb in the visible range of the electromagnetic spectrum, but rather in the UV region. Thus, for the use in photoelectric conversion devices for solar cells, they have to be sensitized with a dye that absorbs in the range of ca. 300 to 2000 nm. In the photosensitive layer, the dye molecules absorb photons of the immersive light which have a sufficient energy. This creates an excited state of the dye molecules which inject an electron into the conduction band of the semi-conductive metal oxide. The semi-conductive metal oxide receives and conveys the electrons to the electrically conductive layer and thus to the working electrode (see below).

### (1) Semi-Conductive Metal Oxide

An n-type semiconductor is preferably used in the present invention, in which conduction band electrons act as a carrier under photo-excitation condition to provide anode current.

Suitable semi-conductive metal oxides are all metal oxides known to be useful on organic solar cells. They include: oxides of titanium, tin, zinc, iron, tungsten, zirconium, hafnium, strontium, indium, cerium, yttrium, lanthanum, vanadium, caesium, niobium or tantalum. Further, composite semiconductors such as M¹ₓM²_{y}O_{z} may be used in the present invention, wherein M, M¹ and M² independently represent a metal atom, O represents an oxygen atom, and x, y and z represent numbers combined with each other to form a neutral molecule. Examples are TiO₂, SnO₂, Fe₂O₃, WO3, ZnO, Nb₂O₅, SrTiO₃, Ta₂O₅, Cs₂O, zinc stannate, complex oxides of the Perowskit type, such as barium titanate, and binary and ternary iron oxides.

Preferred semi-conductive metal oxides are selected from TiO₂, SnO₂, Fe₂O₃, WO3, ZnO, Nb₂O₅, and SrTiO₃. Of these semiconductors, more preferred are TiO₂, SnO₂, ZnO and mixtures thereof. Even more preferred are TiO₂, ZnO and mixtures thereof, particularly preferred being TiO₂.

The metal oxides are preferably present in amorphous or nanocrystalline form. More preferably, they are present as nanocrystalline porous layers. Such layers have a big surface on which a large number of dye molecules can be absorbed, thus resulting in a high absorption of immersing light. The metal oxide layers may also be present in a structured form, such as nanorods. Nanorods offer the advantage of high electron mobility and an improved filling of the pores with the dye.

If more than one metal oxide is used, the two or more metal oxides can be applied as mixtures when the photosensitive layer is formed. Alternatively, a layer of a metal oxide may be coated with one or more metal oxides different therefrom.

The metal oxides may also be present as a layer on a semiconductor different therefrom, such as GaP, ZnP or ZnS.

TiO₂ and ZnO used in the present invention are preferably in anatase-type crystal structure, which in turn is preferably nanocrystalline.

The semiconductor may or may not comprise a dopant to increase the electron conductivity thereof. Preferred dopants are metal compounds such as metals, metal salts and metal chalcogenides.

In the photosensitive layer the semi-conductive metal oxide layer is preferably porous, particularly preferably nanoporous and specifically mesoporous.

Porous material is characterized by a porous, non-smooth surface. Porosity is a measure of the void spaces in a material, and is a fraction of the volume of voids over the total volume. Nanoporous material has pores with a diameter in the nanometer range, i.e. ca. from 0.2 nm to 1000 nm, preferably from 0.2 to 100 nm. Mesoporous material is a specific form of nanoporous material having pores with a diameter of from 2 to 50 nm. “Diameter” in this context refers to the largest dimension of the pores. The pores' diameter can be determined by several porosimetry methods, such as optical methods, imbibition methods, water evaporation method, mercury intrusion porosimetry or gas expansion method.

The particle size of the semi-conductive metal oxide used for producing the semiconductive metal oxide layer is generally in the nm to μm range. The mean size of primary semiconductor particles, which is obtained from a diameter of a circle equivalent to a projected area thereof, is preferably 200 nm or less, e.g. 5 to 200 nm, more preferably 100 nm or less, e.g. 5 to 100 nm or 8 to 100 nm.

Two or more of the semi-conductive metal oxides having a different particle size distribution may be mixed in the preparation of the photosensitive layer. In this case, the average particle size of the smaller particles is preferably 25 nm or less, more preferably 10 nm or less. To improve a light-capturing rate of the photoelectric conversion device by scattering rays of incident light, the semi-conductive metal oxides having a large particle size, e.g. approximately 100 to 300 nm in diameter, may be used for the photosensitive layer.

Preferred as a method for producing the semi-conductive metal oxides are: sol-gel methods described for example in Materia, Vol. 35, No. 9, Page 1012 to 1018 (1996). The method developed by Degussa Company, which comprises preparing oxides by subjecting chlorides to a high temperature hydrolysis in an oxyhydrogen salt, is also preferred.

In the case of using titanium oxide as the semi-conductive metal oxides, the above-mentioned sol-gel methods, gel-sol methods, high temperature hydrolysis methods are preferably used. Of the sol-gel methods, also preferred are such that described in Barbé et al., Journal of American Ceramic Society, Vol. 80, No. 12, Page 3157 to 3171 (1997) and Burnside et al, Chemistry of Materials, Vol. 10, No. 9, Page 2419 to 2425 (1998).

The semi-conductive metal oxides may be applied onto the layer obtained in step (i) or, if carried out, step (ii), by: a method where the layer obtained in step (i) or (ii) is coated with a dispersion or a colloidal solution containing the particles; the above-mentioned sol-gel method; etc. A wet type layer formation method is relatively advantageous for the mass production of the photoelectric conversion device, for improving the properties of the semi-conductive metal oxide dispersion, and for improving the adaptability of the layer obtained in step (i) or (ii), etc. As such a wet type layer formation method, coating methods, printing methods, electrolytic deposition methods and electrodeposition techniques are typical examples. Further, the semi-conductive metal oxide layer may be disposed by: oxidizing a metal; an LPD (liquid phase deposition) method where a metal solution is subjected to ligand exchange, etc.; a sputtering method; a vapor deposition method; a CVD (chemical vapour deposition) method; or an SPD (spray pyrolysis deposition) method where a thermal decomposition-type metal oxide precursor is sprayed on a heated substrate to generate a metal oxide.

The dispersion containing the semi-conductive metal oxides may be prepared by: the sol-gel methods mentioned above; crushing the semiconductor in a mortar; dispersing the semiconductor while grinding it in a mill; synthesizing and precipitating the semiconductive metal oxides in a solvent; etc.

As a dispersion solvent, water or organic solvents such as methanol, ethanol, isopropyl alcohol, citronellol, terpineol, dichloromethane, acetone, acetonitrile, ethyl acetate, etc., mixtures thereof and mixtures of one or more of these organic solvents with water may be used. A polymer such as polyethylene glycol, hydroxyethylcellulose and carboxymethylcellulose, a surfactant, an acid, a chelating agent, etc. may be used as a dispersing agent, if necessary. In particular, polyethylene glycol may be added to the dispersion because the viscosity of the dispersion and the porosity of the semi-conductive metal oxide layer can be controlled by changing the molecular weight of the polyethylene glycol, and the semi-conductive metal oxide layer containing polyethylene glycol is hardly peeled off.

Preferred coating methods include e.g. roller methods and dip methods for applying the semi-conductive metal oxide, and e.g. air-knife methods and blade methods for calibrating the layer. Further, preferable as a method where the application and calibration can be performed at the same time are wire-bar methods, slide-hopper methods, e.g. such as described in U.S. Pat. No. 2,761,791, extrusion methods, curtain methods, etc. Furthermore, spin methods and spray methods may be used. As to wet type printing methods relief printing, offset printing, gravure printing, intaglio printing, gum printing, screen printing, etc. are preferred. A preferable layer formation method may be selected from these methods in accordance with the viscosity of the dispersion and the desired wet thickness.

As already mentioned, the semi-conductive metal oxide layer is not limited to a single layer. Dispersions each comprising the semi-conductive metal oxides having a different particle size may be subjected to a multi-layer coating. Further, dispersions each containing different kinds of semi-conductive metal oxides, binder or additives may be subjected to a multi-layer coating. The multi-layer coating is also effectively used in case the thickness of a single layer is insufficient.

Generally, with increasing thickness of the semi-conductive metal oxide layer, which equals the thickness of the photosensitive layer, the amount of the dye incorporated therein per unit of projected area increases resulting in a higher light capturing rate. However, because the diffusion distances of the generated electrons also increase, higher loss rates owing to recombination of the electric charges is to be expected. Moreover, customarily used dyes such as phthalocyanins and porphyrins have a high absorption rates, so that thin layers or films of the metal oxide are sufficient. Consequently, the preferable thickness of the semi-conductive metal oxide layer is 0.1 to 100 μm, more preferably 0.1 to 50 μm, even more preferably 0.1 to 30 μm, in particular 0.1 to 20 μm and specifically 0.5 to 3 μm.

A coating amount of the semi-conductive metal oxides per 1 m² of the substrate is preferably 0.5 to 100 g, more preferably 3 to 50 g.

After applying the semi-conductive metal oxide(s) onto the layer obtained in step (i) or (ii), the obtained product is preferably subjected to a heat treatment (sintering step), to electronically contact the metal oxide particles with each other and to increase the coating strength and the adherence thereof with the layer below. The heating temperature is preferably 40 to 700° C., more preferably 100 to 600° C. The heating time is preferably 10 minutes to 10 hours.

However, in case the electrically conductive layer contains a thermosensitive material having a low melting point or softening point such as a polymer film, the product obtained after the application of the semi-conductive metal oxide is preferably not subjected to a high temperature treatment because this may damage such a substrate. In this case, the heat treatment is preferably carried out at a temperature as low as possible, for example, 50 to 350° C. In this case, the semi-conductive metal oxide is preferably one with smaller particles, in particular having a medium particle size of 5 nm or less. Alternatively, a mineral acid or a metal oxide precursor can be heat-treated at such a low temperature.

Further, the heat treatment may be carried out while applying an ultraviolet radiation, an infrared radiation, a microwave radiation, an electric field, an ultrasonic wave, etc. to the semi-conductive metal oxides, in order to reduce the heating temperature. To remove unnecessary organic compounds, etc., the heat treatment is preferably carried out in combination with evacuation, oxygen plasma treatment, washing with pure water, a solvent or a gas, etc.

If desired, it is possible to form a blocking layer on the layer of the semi-conductive metal oxide before sensitizing it with a dye in order to improve the performance of the semi-conductive metal oxide layer. Such a blocking layer is usually introduced after the aforementioned heat treatment. An example of forming a blocking layer is immersing the semi-conductive metal oxide layer into a solution of metal alkoxides such as titanium ethoxide, titanium isopropoxide or titanium butoxide, chlorides such as titanium chloride, tin chloride or zinc chloride, nitrides or sulfides and then drying or sintering the substrate. For instance, the blocking layer is made of a metal oxide, e.g. TiO₂, SiO₂, Al₂O₃, ZrO₂, MgO, SnO₂, ZnO, Eu₂O₃, Nb₂O₅ or combinations thereof, TiCl₄, or a polymer, e.g. poly(phenylene oxide-co-2-allylphenylene oxide) or poly(methylsiloxane). Details of the preparation of such layers are described in, for example, Electrochimica Acta 40, 643, 1995; J. Am. Chem. Soc 125, 475, 2003; Chem. Lett. 35, 252, 2006; J. Phys. Chem. B, 110, 1991, 2006. Preferably, TiCl₄ is used. The blocking layer is usually dense and compact, and is usually thinner than the semi-conductive metal oxide layer.

As already said, it is preferable that the semi-conductive metal oxide layer has a large surface area to adsorb a large number of dye molecules. The surface area of the semiconductive metal oxide layer is preferably 10 times or more, more preferably 100 times or more higher than its projected area.

### (2) Dye

The dye used as chromophoric substance for the photosensitive layer is not particularly limited if it can absorb light particularly in the visible region and/or near infrared region (especially from ca. 300 to 2000 nm) and can sensitize the semi-conductive metal oxide. Examples are metal complex dyes (see for example U.S. Pat. No. 4,927,721, U.S. Pat. No. 5,350,644, EP-A-1176646, Nature 353, 1991, 737-740, Nature 395, 1998, 583-585, U.S. Pat. No. 5,463,057, U.S. Pat. No. 5,525,440, U.S. Pat. No. 6,245,988, WO 98/50393), indoline dyes (see for example (Adv. Mater. 2005, 17, 813), oxazine dyes (see for example U.S. Pat. No. 6,359,211), thiazine dyes (see for example U.S. Pat. No. 6,359,211), acridine dyes (see for example U.S. Pat. No. 6,359,211), prophyrin dyes, methine dyes (preferably polymethine dyes such as cyanine dyes, merocyanine dyes, squalilium dyes, etc; see for example U.S. Pat. No. 6,359,211, EP 892411, EP 911841, EP 991092, WO 2009/109499) and rylene dyes (see for example JP-A-10-189065, JP 2000-243463, JP 2001-093589, JP 2000-100484, JP 10-334954, New J. Chem. 26, 2002, 1155-1160 and in particular DE-A-10 2005 053 995 and WO 2007/054470).

The dye is preferably selected from the group consisting of metal complex dyes, porphyrin dyes, merocyanine dyes and rylene dyes, more preferably from ruthenium complex dyes and rylene dyes and particularly preferably form rylene dyes (in particular those described in DE-A-10 2005 053 995 and WO 2007/054470).

To make the photoelectric conversion wave range of the photoelectric conversion device larger, and to increase the photoelectric conversion efficiency, two or more kinds of the dyes may be used as a mixture or in combination thereof. In the case of using two or more kinds of the dyes, the kinds and the ratio of the dyes may be selected in accordance with the wave range and the strength distribution of the light source.

For instance the absorption of the rylene dyes depends on the extent of the conjugated system. The rylene derivatives of DE-A-10 2005 053 995 have an absorption of from 400 nm (perrylene derivatives I) to 900 nm (quaterrylene derivatives I). Terrylene-based dyes absorb from about 400 to 800 nm. In order to obtain absorption over a range of the electromagnetic waves as large as possible it is thus advantageous to use a mixture of rylene dyes with different absorption maxima.

The dye preferably has an interlocking or anchor group, which can interact or adsorb to the surface of the semi-conductive metal oxides. Preferred interlocking groups include acidic groups such as —COON, —OH, —SO₃H, —P(O)(OH)₂ and —OP(O)(OH)₂, and π-conductive chelating groups such as oxime group, dioxime group, hydroxyquinoline group, salicylate group and α-ketoenolate group. Anhydride groups are also suitable as they react in situ to carboxylic groups. Among them, preferred are acidic groups, particularly preferred are —COON, —P(O)(OH)₂ and —OP(O)(OH)₂. The interlocking group may form a salt with an alkaline metal, etc. or an intramolecular salt. In the case of polymethine dyes, an acidic group such as squarylium ring group or croconium ring group formed by the methine chain may act as the interlocking group.

Preferably, the dye has on the distal end (i.e. the end of the dye molecule opposite the anchor group) one or more electron donating groups which facilitate the regeneration of the dye after having donated an electron to the semi-conductive metal oxide and which optionally also prevent recombination with the donated electrons.

The rylene dyes useful in the present invention are for example the various perylene-3,4:9,10-tetracarboxylic acid derivatives described in JP 3968819, JP 4211120, JP 10189065 and JP 2000/100484 for use in semiconductor solar cells. Those dyes are specifically: perylenetetra-carboximides which bear carboxyalkyl, carboxyaryl, carboxyarylalkyl or carboxyalkylaryl radicals on the imide nitrogen atoms and/or have been imidized with para-diaminobenzene derivatives in which the nitrogen atom of the amino group in the para-position has been substituted by two further phenyl radicals or is part of a heteroaromatic tricyclic system; perylene-3,4:9,10-tetracarboxylic monoanhydride monoimides which bear the aforementioned radicals or alkyl or aryl radicals without further functionalization on the imide nitrogen atom, or semicondensates of perylene-3,4:9,10-tetracarboxylic dianhydride with 1,2-diaminobenzenes or 1,8-diaminonaphthalenes which are converted by further reaction with primary amine to the corresponding diimides or double condensates; condensates of perylene-3,4:9,10-tetracarboxylic dianhydride with 1,2-diaminobenzenes which have been functionalized by carboxyl or amino radicals; and perylene-3,4:9,10-tetracarboximides which have been imidized with aliphatic or aromatic diamines.

Further rylene dyes useful in the present invention are perylene-3,4-dicarboxylic acid derivatives as described in New J. Chem. 26, p. 1155-1160 (2002) Specific mention is made of 9-dialkylaminoperylene-3,4-dicarboxylic anhydrides and perylene-3,4-dicarboximides which are substituted in the 9-position by dialkylamino or carboxymethylamino and bear a carboxymethyl or a 2,5-di(tert-butyl)phenyl radical on the imide nitrogen atom.

Rylene dyes that are specifically used in the present invention are those described in US 2008/0269482, in particular the anhydrides and dicarboximides of the 9-amino substituted perylene-3,4-dicarboxylic acids and the corresponding terrylene derivatives of the formula (II),

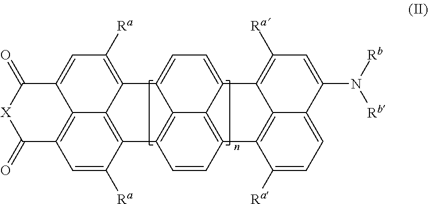

wherein
X is O, NH, N-phenyl-COOH or N—(CH₂)ₘ—COOH, with m being an integer from 1 to 4;
n is 0 or 1;
R^{a} is hydrogen, aryloxy, arylthio or diarylamino, where the aryl groups in the 3 last-mentioned radicals may be unsubstituted or substituted with 1 to 3 radicals preferably selected from alkyl, alkoxy and aryl;
R^{a′} is defined like R^{a} and is preferably hydrogen in case n=0, and is preferably identical to R^{a} in case n=1;
R^{b} is aryl that may be unsubstituted or substituted with 1 to 3 radicals preferably selected from alkyl, alkoxy, dialkylamino, aryl and hetaryl;
R^{b′} is defined like R^{b} and is preferably identical to R^{b}, or
R^{b} and R^{b′} together with the nitrogen atom to which they are bond form a heterocylce.

Particularly preferred in the context of the present invention are dyes of the formula (II) with n being 0 and X being N-phenyl-COOH or N—CH₂—COOH. Specifically preferred is the perylene dye “ID176” disclosed in U. B. Cappel et al., J. Phys. Chem. C, 113, 33, 14595-14597, 2009, which is a compound of the formula (II) wherein X is N—CH₂—COOH, n is O, R^{a} and R^{a′} are hydrogen and R^{b} and R^{b′} are each 4-(1,1,3,3-tetramethyl butyl)-phenyl.

The dye may be adsorbed to the semi-conductive metal oxides by bringing these components into contact with each other, e.g. by soaking the product obtained after the application of the semi-conductive metal oxide layer in a dye adsorption solution, or by applying the dye adsorption solution to the semi-conductive metal oxide layer. In the former case, a soaking method, a dipping method, a roller method, an air-knife method, etc. may be used. In the soaking method. The dye may be adsorbed at room temperature, or under reflux while heating as described in JP 7249790. As an applying method of the latter case, a wire-bar method, a slide-hopper method, an extrusion method, a curtain method, a spin method, a spray method, etc. may be used. Further, the dye may be applied to the semi-conductive metal oxide layer by an ink-jet method onto an image, thereby providing a photoelectric conversion surface having a shape of the image. These methods can be used also in the case where the dye is adsorbed on the semi-conductive metal oxide while the semi-conductive metal oxide is treated with at least one hydroxamic acid or its salt, thus, the dye adsorption solution may contain the one or more hydroxamic acids or their salts. Preferably, the dye, e.g. in the form of a suspension or solution, is brought into contact with the semi-conductive metal-oxide when this is freshly sintered, i.e. still warm. The contact time should be sufficiently long to allow absorption of the dye to the surface of the metal oxide. The contact time is typically from 0.5 to 24 h.

If more than one dye is to be applied, the application of the two or more dyes can be carried out simultaneously, e.g. by using a mixture of two or more dyes, or subsequently by applying one dye after the other.

The dye may also be applied in mixture with the at least one hydroxamic acid or its salt. Additionally or alternatively the dye may be applied in combination with the charge transfer material.

The dye unadsorbed on the semi-conductive metal oxide layer is preferably removed by washing immediately after the dye adsorption process. The washing is preferably carried out by a wet-type washing bath with a polar solvent, in particular a polar organic solvent, for example acetonitrile or an alcohol solvent.

The amount of the dye adsorbed on the semi-conductive metal oxides is preferably 0.01 to 1 mmol per 1 g of the semi-conductive metal oxides. Such an adsorption amount of the dye usually effects a sufficient sensitization to the semiconductors. Too small an amount of the dye results in insufficient sensitization effect. On the other hand, unadsorbed dye may float on the semi-conductive metal oxides resulting in a reduction of the sensitization effect.

To increase the adsorption amount of the dye the semi-conductive metal oxide layer may be subjected to a heat treatment before the dye is adsorbed thereon. After the heat treatment, it is preferable that the dye is quickly adsorbed on the semi-conductive metal oxide layer having a temperature of 60 to 150° C. before the layer is cooled to room temperature, to prevent water from adsorbing onto the semi-conductive metal oxide layer.

### (3) Hydroxamic Acid and Salts Thereof

Reference is made to what has been said before.

### (4) Passivating Material

In order to prevent recombination of the electrons in the semi-conductive metal oxide with the charge transfer layer a passivating layer can be provided on the semiconductive metal oxide. The passivating layer can be provided before the absorption of the dye and also of the hydroxamic acid or its salt, or after the dye absorption process and the treatment with the hydroxamic acid or is salt. Suitable passivating materials are aluminium salts, Al₂O₃, silanes, such as CH₃SiCl₃, metal organic complexes, especially Al³⁺ complexes, 4-tert-butyl pyridines, MgO, 4-guanidino butyric acid and hexadecyl malonic acid.

The passivating layer is preferentially very thin.

(D) Charge Transfer Layer [Step (iv)]

The charge transfer layer replenishes electrons to the oxidized dye. The charge transfer layer may be composed of (i) an ion conductive electrolyte composition or (ii) charge-transporting material utilizing charge transport mediated by free charge carriers. Examples of the ion conductive electrolyte composition (i) include molten salt electrolyte compositions containing a redox couple; electrolysis solutions where a redox couple is dissolved in a solvent; so-called gel electrolyte compositions where a solution including a redox couple is penetrated into a polymer matrix; solid electrolyte compositions; etc. Examples of charge-transporting material (ii) include electron-transporting materials and hole-transporting materials. These materials may be used in combination with each other.

The charge transfer layer used in this invention is preferably solid, preferably composed of a hole-transporting material (a solid p-semiconductor).

### (1) Molten Salt Electrolyte Composition

The molten salt electrolyte compositions may be used for the charge transfer layer where a sufficient durability in combination with a good energy conversion efficiency η of the photoelectric conversion device is sought. The molten salt electrolyte composition comprises a molten salt electrolyte having a low melting point. For the use in the present invention salts of a wide variety may be selected as the molten salt electrolyte. Useful examples of such salts are for instance pyridinium salts, imidazolium salts, and triazolium salts disclosed e.g. in WO 95/18456 and EP 0718288. The molten salt electrolyte preferably has a melting point of 100° C. or less, and it is particularly preferably liquid at room temperature.

Though the molten salt electrolyte composition may comprise a solvent described below, it particularly preferably comprises no solvent. The content of the molten salt electrolyte is preferably 50 weight % or more, particularly preferably 90 weight % or more, based on the entire composition of the charge transfer layer. The weight ratio of iodine salts that are preferably contained in the molten salt electrolyte composition is preferably 50 weight % or more based on the entire salts contained therein.

The molten salt electrolyte composition preferably comprises iodine. The iodine-content is preferably 0.1 to 20 weight %, more preferably 0.5 to 5 weight % based on the entire composition.

The molten salt electrolyte composition may also contain a basic compound such as t-butylpyridine, 2-picoline, 2,6-lutidine, etc., as described in J. Am. Ceram. Soc., 80 (12), 3157 to 3171 (1997). The concentration of the basic compound therein is preferably 0.05 to 2 M.

### (2) Electrolysis Solution

The electrolysis solution used in the present invention is preferably composed of an electrolyte, a solvent and optionally an additive. The electrolyte may be: a combination of 12 and an iodide (a metal iodide such as LiI, NaI, KI, CsI and CaI₂, a quaternary ammonium iodide such as a tetralkylammonium iodide, pyridinium iodide and imidazolium iodide, etc.); a combination of Br₂ and a bromide (a metal bromide such as LiBr, NaBr, KBr, CsBr and CaBr₂, a quaternary ammonium bromide such as a tetralkylammonium bromide and pyridinium bromide, etc.); a metal complex such as a ferrocyanide-ferricyanide and a ferrocene-ferricinium ion; a sulfur compound such as sodium polysulfide and alkylthiol-alkyldisulfide; a viologen dye; hydroquinone-quinone; etc. Among them, preferred is a combination of I₂ and LiI or a quaternary ammonium iodide. Also, a mixture of several electrolytes may be used.

The concentration of the electrolyte in the electrolysis solution is preferably 0.1 to 10 M, more preferably 0.2 to 4 M. Further, the electrolysis solution may comprise iodine, and the concentration of iodine therein is preferably 0.01 to 0.5 M.

The solvent used for the electrolysis solution is preferably one that has a low viscosity and allows for a high ionic mobility and thus a good ionic conductibility. Examples of the solvent include: carbonates such as ethylene carbonate and propylene carbonate; heterocyclic compounds such as 3-methyl-2-oxazolidinone; ethers such as dioxan and diethyl ether; chain ethers such as ethyleneglycol dialkylethers, propyleneglycol dialkylethers, polyethyleneglycol dialkylethers and polypropyleneglycol dialkylethers; alcohols such as methanol, ethanol, ethyleneglycol monoalkylethers, propyleneglycol monoalkylethers, polyethyleneglycol monoalkylethers and polypropyleneglycol monoalkylethers; glycols such as ethylene glycol, propylene glycol, polyethylene glycol, polypropylene glycol and glycerin; nitrile compounds such as acetonitrile, glutarodinitrile, methoxyacetonitrile, propionitrile and benzonitrile; dimethylsulfoxide (DMSO) and sulfolane; water; etc. These solvents may be used in combination with each other.

The electrolysis solution may also contain a basic compound such as t-butylpyridine, 2-picoline, 2,6-lutidine, etc., as described in J. Am. Ceram. Soc., 80 (12), 3157 to 3171 (1997). The concentration of the basic compound therein is preferably 0.05 to 2 M.

### (3) Gel Electrolyte Composition

The molten salt electrolyte composition, the electrolysis solution, etc. mentioned above may be gelled or solidified to prepare a gel electrolyte composition. Gelation may be achieved by: adding a polymer; adding an oil-gelling agent; polymerization of monomers including a multifunctional monomer; a crosslinking reaction of a polymer; etc.

In the case where the gel electrolyte composition is prepared by adding a polymer, compounds described in “Polymer Electrolyte Reviews 1 and 2” edited by J. R. MacCallum and C. A. Vincent, Elsevier, London (1987 and 1989), may be used as the polymer. Of these compounds, polyacrylonitrile and poly(vinylidene fluoride) are preferred.

In the case where the gel electrolyte composition is prepared by adding an oil-gelling agent, compounds described in J. Am. Chem. Soc., 111, 5542 (1989), J. Chem. Soc., Chem. Commun., 390 (1993), Angew. Chem. Int. Ed. Engl., 35, 1949 (1996), Chem. Lett., 885 (1996), J. Chem. Soc., Chem. Commun., 545 (1997), etc. may be used as the oil-gelling agent. Of these compounds, preferred are those having an amide structure.

In the case where the gel electrolyte composition is prepared by a cross-linking reaction of a polymer, it is preferable that a polymer containing groups having cross-linking reactivity is used in combination with a cross-linking agent. The groups having a cross-linking reactivity are preferably amino groups or nitrogen-containing heterocyclic groups such as pyridyl groups, imidazolyl groups, thiazolyl groups, oxazolyl groups, triazolyl groups, morpholyl groups, piperidyl groups, piperazyl groups, etc. The cross-linking agent is preferably an electrophilic agent having a plurality of functional groups that can be attacked by a nitrogen atom of an amino group or of the aforementioned heterocyclic groups, for example, multi-functional alkyl halides, aralkyl halides, sulfonates, acid anhydrides, acyl chlorides, isocyanates, α,β-unsaturated sulfonyl compounds, α,β-unsaturated carbonyl compounds, α,β-unsaturated nitrile compounds, etc.

### (4) Hole-Transporting Material

In the present invention an inorganic solid hole-transporting material, an organic solid hole-transporting material or a combination thereof may be used for the charge transfer layer.

### (a) Inorganic Hole-Transporting Material

The inorganic hole-transporting material may be a p-type inorganic compound semiconductor, which is preferably a compound comprising monovalent copper such as CuI, CuSCN, CuInSe₂, Cu(In,Ga)Se₂, CuGaSe₂, Cu₂O, CuS, CuGaS₂, CuInS₂, CuAlSe₂, etc. Among them, CuI and CuSCN are preferred, and CuI is the most preferred. GaP, NiO, CoO, FeO, Bi₂O₃, MoO₂, Cr₂O₃, etc. may also be used as a p-type inorganic compound semiconductor.

### (b) Organic Hole-Transporting Material

Examples of the organic hole-transporting material useful in this invention include polymers such as polypyrrole disclosed e.g. in K. Murakoshi, et al., Chem. Lett., 471, 1997, and polyacetylene, poly(p-phenylene), poly(p-phenylenevinylene), polythienylenevinylene, polythiophene, polyaniline, polytoluidine and derivatives thereof disclosed in “Handbook of Organic Conductive Molecules and Polymers”, Vols. 1 to 4, edited by H. S. Nalwa, published by Wiley (1997), and poly(3,4-ethylenedioxythiophene), poly(4-undecyl-2,2′-biothiophene), poly(3-octylthiophene), poly(triphenyldiamine) and carbazole-based polymers such as poly(n-vinylcarbazole).

Low molecular weight organic hole-transporting materials that are also useful in this invention include aromatic amines disclosed e.g. in Nature, Vol. 395, Oct. 8, 1998, Page 583 to 585, WO 97/10617, U.S. Pat. No. 4,923,774 and U.S. Pat. No. 6,084,176; triphenylenes disclosed e.g. in JP 11176489; oligothiophene compounds disclosed e.g. in Adv. Mater., 9, No. 7, 557, 1997, Angew. Chem. Int. Ed. Engl., 34, 3, 303 to 307, 1995, J. Am. Chem. Soc., Vol. 120, 4, 664 to 672, 1998; hydrazone compounds, silazane compounds disclosed e.g. in U.S. Pat. No. 4,950,950, silanamine derivatives, phosphamine derivatives, quinacridone compounds, stilbene compounds such as 4-di-p-tolylamino-stilbene and 4-(di-p-tolylamino)-4′-[4-di-p-tolylamino)-styryl]stilbene, triazole derivatives, oxadiazole derivatives, imidazole derivatives, polyarylalkane derivatives, pyrazoline derivatives, pyrazolone derivatives, amino-substituted chalcone derivatives, oxazole derivatives, styrylanthracene derivatives, fluorenone derivatives, and polysilane derivatives. These compounds may be used alone or in admixture of two or more.

Preferred organic hole-transporting materials for use in this invention are spirobifluorenes (see for example US 2006/0049397). A particularly preferred spirobifluorene is 2,2′,7,7′-tetrakis(N,N-di-p-methoxyphenyl-amine)9,9′-spirobifluorene (“OMeTAD”) disclosed for example in U. Bach et al., Nature 395, 583-585, 1998.

As also described in this reference to the organic hole-transporting material may be added a dopant, such as N(PhBr)₃SbCl₆, to introduce free charge carriers in the hole-transporting material by oxidation, and a salt, such as Li[CF₃SO₂)N, to achieve potential-control on the surface of the titanoxide semiconductor.

As already said, the charge transfer layer is preferably solid and comprises more preferably a solid hole-transporting material, even more preferably a solid organic hole-transporting material and in particular a spirobifluorene derivative as an organic hole-transporting material.

According to a particularly preferred embodiment of the invention the charge transfer layer comprises OMeTAD and Li[CF₃SO₂)N.

### (5) Method for Forming the Charge Transfer Layer

The charge transfer layer may be provided for instance by any of the following two methods. One is a method where the counter electrode is stuck on the photosensitive layer beforehand and the material for the charge transfer layer in the liquid state is made to penetrate a gap therebetween. Another is a method where the charge transfer layer is directly disposed on the photosensitive layer, the counter electrode being then disposed thereon.

In the former method, the material for the charge transfer layer may be made to penetrate the gap by a normal pressure process utilizing capillarity, or by a reduced pressure process.

In the case of providing a wet charge transfer layer by the latter method, the wet charge transfer layer is applied to the photosensitive layer, the counter electrode is disposed on the wet charge transfer layer without drying it and edges thereof are subjected to a treatment for preventing liquid-leakage, if necessary. In the case of providing a gel charge transfer layer by the latter method, the charge transfer material may be applied in the liquid state and gelled by polymerization, etc. In this case, the counter electrode may be disposed on the charge transfer layer before or after drying and fixing the charge transfer layer.

The charge transfer layer composed of the electrolysis solution, the wet organic hole-transporting material, the gel electrolyte composition, etc. may be disposed for example by a roller method, a dip method, an air-knife method, an extrusion method, a slide-hopper method, a wire-bar method, a spin method, a spray method, a cast method, various printing methods, similarly to the case of forming the semi-conductive metal oxide layer, or adsorbing a dye to the semiconductor mentioned above.

The charge transfer layer composed of the solid electrolyte, the solid hole transporting material, etc. may be formed by a dry film-forming method such as a vacuum deposition method and a CVD method, and followed by disposing the counter electrode thereon. The organic hole-transporting material may be made to penetrate into the photosensitive layer by a vacuum deposition method, a cast method, a coating method, a spin-coating method, a soaking method, an electrolytic polymerization method, a photo-polymerization method, a combination of these methods, etc. The inorganic hole-transporting material may be made to penetrate into the photosensitive layer by a cast method, a coating method, a spin-coating method, a soaking method, an electrolytic deposition method, an electroless deposition method, etc.

(E) Counter Electrode [Step (v)]

As already said, the counter electrode is the counter electrically conductive layer, which is optionally supported by a substrate as defined above. Examples of the electrically conductive material used for the counter electrically conductive layer include: metals such as platinum, gold, silver, copper, aluminum, magnesium and indium; mixtures and alloys thereof, especially of aluminum and silver; carbon; electrically conductive metal oxides such as indium-tin composite oxides and fluorine-doped tin oxides. Among them, preferred are platinum, gold, silver, copper, aluminum and magnesium, and particularly preferred silver or gold. Specifically, silver is used. Suitable electrodes are moreover mixed inorganic/organic electrodes and polylayer electrodes, such as LiF/AI electrodes. Suitable electrodes are described for example in WO 02/101838 (especially pp 18-20)

The substrate of the counter electrode is preferably made of a glass or a plastic to be coated or vapor-deposited with the electrically conductive material. The counter electrically conductive layer preferably has a thickness of 3 nm to 10 μm, although the thickness is not particularly limited.

Light may be irradiated from any one or both sides of the electrically conductive layer provided in step (i) and the counter electrode provided in step (v), so that at least one of them should be substantially transparent to have light reached to the photosensitive layer. From a viewpoint of improving electric generation efficiency, it is preferable that the electrically conductive layer provided in step (i) is substantially transparent to incident light. In this case, the counter electrode preferably has a light-reflective property. Such a counter electrode may be composed of a glass or a plastic having a vapor-deposited layer of metal or electrically conductive oxide, or metal thin film. This type of device, which is also called “concentrator”, is described for example in WO 02/101838 (especially on pp 23-24).

The counter electrode may be disposed by applying metal-plating or vapor-depositing (physical vapor deposition (PVD), CVD, etc.) the electrically conductive material directly onto the charge transfer layer. Similar as with the conductive support, it is preferable that a metal lead is used to reduce the resistance of the counter electrode. The metal lead is particularly preferably used for a transparent counter electrode. Preferable embodiments of the metal lead used for the counter electrode are the same as those of the metal lead used for the conductive layer mentioned above.

### (F) Others

Functional layers such as a protective layer and a reflection-preventing layer may be disposed on any one or both of the conductive layer and the counter electrode. The functional layers may be disposed by a method selected in accordance with the materials used therefor, such as a coating method, a vapor-deposition method and a sticking method.

### (G) Interior Structure of Photoelectric Conversion Device

As described above, the photoelectric conversion device may have various interior structures according to the desired end use. The structures are classified into two major forms, a structure allowing light incidence from both faces, and a structure allowing it from only one face. In the first case, the photosensitive layer, the charge transfer layer and the other optionally present layers are disposed between a transparent electrically conductive layer and a transparent counter electrically conductive layer. This structure allows light incidence from both faces of the device. In the second case, one of the transparent electrically conductive layer and the transparent counter electrically conductive layer is transparent, while the other is not. As a matter of course, if the electrically conductive layer is transparent, light immerses from the electrically conductive layer side, while in case of the counter electrically conductive layer being transparent, light immerses from the counter electrode side.

The invention further relates to a photoelectric conversion device obtainable by the process of the invention.

Thus, the photoelectric conversion device of the invention comprises a photosensitive layer containing at least one semi-conductive metal oxide on which at least one chromophoric substance is adsorbed, wherein said semi-conductive metal oxide is treated with at least one hydroxamic acid and/or at least one salt thereof which are essentially transparent in the electromagnetic wavelength range of 400 to 1000 nm. With respect to suitable and preferred semi-conductive metal oxides, hydroxamic acids and their salts and the device's assembly, reference is made to what has been said hereinbefore.

More preferably, the photoelectric conversion device of the invention comprises
I) an electrically conductive layer;
II) optionally an undercoating layer,
III) a photosensitive layer, wherein the photosensitive layer contains a semiconductive metal oxide that is sensitized by a chromophoric substance and treated with at least one essentially transparent hydroxamic acid and/or at least one essentially transparent salt thereof; IV) a charge transfer layer; and
V) a counter electrically conductive layer.

As regards the layers and components of which the photoelectric conversion device of the invention is composed, reference is made to what has been said above. As already said, the term “layer” in this context does not necessarily imply that each layer is physically strictly separated from the other layers. In fact, the layers may interpenetrate each other. For instance, the material of which the charge transfer layer is composed may permeate into the photosensitive layer and come into close contact with the semiconductive metal oxide and the dye, so that a fast charge transfer is possible.

In the photoelectric conversion device outlined herein before, in the case of using an n-type semi-conductive metal oxide, light immersing into the photosensitive layer excites the dye, and excited high energy electrons therein are transported to a conduction band of the semi-conductive metal oxides where they are diffused to reach to the electrically conductive layer. At this time, the dye is in oxidized form. In a photoelectric cell (see below) comprising the photoelectric conversion device, electrons in the electrically conductive layer are returned to the oxidized dye through the counter electrically conductive layer and the charge transfer layer while working in the external circuit, so that the dye is regenerated. The photosensitive layer generally acts as a negative electrode or a photoanode, and the counter electrically conductive layer generally acts as a positive electrode. In a boundary of each layer such as a boundary between the electrically conductive layer and the photosensitive layer, a boundary between the photosensitive layer and the charge transfer layer, a boundary between the charge transfer layer and the counter electrically conductive layer, etc., components of each layer may be diffused and mixed.

Without wishing to be bound to theory, it is believed that the treatment with one or more hydroxamic acids or their salts results in an enhanced energy conversion efficiency η of the photoelectric conversion device according to the invention, because of the variation in proton concentration on the metal oxide surface, shifting the conduction band to more positive potentials, in the case of hydroxamic acids and thereby facilitating electron injection from the dye, or to more negative potentials, thereby increasing the open-circuit voltage, in case of hydroxamates. Furthermore, it is proposed that these additives, especially but not exclusively the hydroxamates, help to reduce dye aggregation and at the same time filling the spaces between dye molecules resulting in a better surface coverage of the metal oxide and thereby reducing the unwanted recombination of electrons in the metal oxide with holes in the charge transport layer. It also seems that the dependence of solid-state dye sensitized solar cells on the quality of the undercoating layer is diminished through the use of such additives. Lastly, such additives tend to have a positive influence on device stability.

These hypotheses are supported by the facts that, depending on the dye employed, the use of hydroxamic acids often leads in particular to an increase of the short circuit current I_{sc} and that the use of hydroxamates in either the simultaneous treatment method or the pre-treatment method often leads in particular to an increase of the open circuit voltage V_{oc}.

### Photoelectric Cell

The present invention also relates to a photoelectric cell, preferably a solar cell, comprising the photoelectric conversion device as described above.

A photoelectric cell is constituted by connecting a photoelectric conversion device to an external circuit to electrically work or generate electricity in the external circuit. Such a photoelectric cell that has the charge transfer layer composed of ion conductive material is referred to as a photo-electrochemical cell. A photoelectric cell intended for power generation using solar light is referred to as a solar cell.

Thus, the photoelectric cell of the present invention is constituted by connecting the photoelectric conversion device of the present invention to an external circuit to electrically work or generate electricity in the external circuit. Preferably, the photoelectric cell is a solar cell, i.e. a cell intended for power generation using solar light.

The side face of the photoelectric cell is preferably sealed with a polymer or an adhesive agent, etc. to prevent deterioration and volatility of the content in the cell. The external circuit is connected to the conductive support and the counter electrode via a lead. Various known circuits may be used in the present invention.

In the case where the photoelectric conversion device of the present invention is applied to the solar cell, the interior structure of the solar cell may be essentially the same as that of the photoelectric conversion device mentioned above. The solar cell comprising the photoelectric conversion device of the present invention may have a known module structure. In generally known module structures of solar cells, the cell is placed on a substrate of metal, ceramic, etc. and covered with a coating resin, a protective glass, etc., whereby light is introduced from the opposite side of the substrate. The solar cell module may have a structure where the cells are placed on a substrate of a transparent material such as a tempered glass to introduce light from the transparent substrate side. Specifically, a super-straight type module structure, a substrate type module structure, a potting type module structure, substrate-integrated type module structure that is generally used in amorphous silicon solar cells, etc. are known as the solar cell module structures. The solar cell comprising the photoelectric conversion device of the present invention may have a module structure which is properly selected e.g. from the above structures which may be adapted in accordance with the respective requirements of a specific use.

The solar cell of the invention may be used in a tandem cell. Thus, the invention also relates to a tandem cell comprising the dye-sensitized solar cell of the invention and an organic solar cell.

Tandem cells are principally known and are described for example in WO 2009/013282. The tandem cells of the invention may be made as those described in WO 2009/013282, where the solar cell of the invention however replaces the dyesensitized solar cell described in this reference.

The invention also relates to the use of hydroxamic acids and/or of salts thereof as defined above for enhancing the energy conversion efficiency η of dye-sensitized photoelectric conversion devices and of course also of photoelectric cells, especially solar cells, comprising them.

### EXAMPLES

The present invention will be illustrated in more detail by the following examples without limiting the scope of the invention in any way.

### General Preparation of a Solar Cell:

In order to test the suitability of the compounds of formula I as additives in solar cells, solar cells were produced as follows.

The base material used was glass plaques coated with fluorine-doped tin oxide (FTO), and of dimensions 25 mm×15 mm×3 mm (Hartford TEC 15), which had been treated successively with glass cleaner, fully demineralized water and acetone, in each case in an ultrasound bath for 5 min, then boiled in isopropanol for 10 min, and dried in a nitrogen stream.

An undercoating layer consisting of solid TiO₂ was deposited on the FTO using a spray-pyrolysis method described in Electrochim. Acta, 40, 643 to 652 (1995). On top of the undercoating layer a paste of TiO₂ (Dyesol, 18 NR-T) was distributed and sintered for 1 hour at 450° C. to afford a mesoporous layer of TiO₂ having a thickness of 3 μm.

The intermediate prepared this way was then treated with TiCl₄ as described by M. Grätzel et al., Adv. Mater. 18, 1202 (2006). After sintering the sample was cooled to 60 to 80° C.

In case of pre-treatment with a hydroxamic acid or its salt the sample was soaked in a 5 mM solution of the hydroxamic acid or its salt in ethanol as treatment liquid, washed in a bath of pure ethanol, briefly dried in a nitrogen stream and subsequently immersed in a 0.5 mM solution of the perylene dye ID176 (Cappel et al., J. Phys. Chem. Lett. C, 2009, 113, 14595-14597) in dichloromethane for 12 hours. Afterwards the sample was rinsed with dichoromethane and dried in a nitrogen stream. The hydroxamic acids used in this pre-treatment method are listed in table 2 and the hydroxamates used in this pre-treatment method are listed in table 3.

In case of post-treatment with a hydroxamic acid or its salt the sample was initially immersed in a 0.5 mM solution of the perylene dye ID176 in dichloromethane for 12 hours. The sample was then rinsed with dichoromethane and dried in a nitrogen stream. Afterwards the sample was soaked in a 5 mM solution of a hydroxamic acid or its salt in ethanol as treatment liquid, washed in a bath of pure ethanol and briefly dried in a nitrogen stream. The hydroxamic acids or the salts thereof used in this post-treatment method are listed in table 4.

Following either the pre-treatment or the post-treatment a hole-transporting material as a charge transfer layer was applied to the photosensitive layer. To this end a solution of OMeTAD (Merck group) in chlorobenzene was prepared and mixed with a 0.3 solution of LiN(SO₂CF₃)₂ (Sigma-Aldrich group) in cyclohexanone. 75 μl of this solution was deposited on the sample and let soak for 30 seconds. Afterwards the supernatant solution was removed by centrifugation at 2000 rpm and dried in ambient air for 3 hours.

The counter electrode was applied by thermal metal vapor deposition in vacuum. To this end the sample was equipped with a mask in order to deposit 4 separated rectangular counter electrodes with dimensions of about 5 mm×4 mm, each of which was contacted via contact areas of 3 mm×2 mm to the charge transfer layer. The metal used was silver which was vaporized at a rate of 0.1 nm/s with a pressure of 5×10⁻⁵ mbar, so that a layer 200 nm thick was formed.

To determine the energy conversion efficiency η, the particular current/voltage characteristic was measured with a source meter model 2400 (Keithley Instruments Inc.) under irradiation with a xenon lamp (LOT Oriel group) with an AM1.5 filter (LOT Oriel group) as a sun simulator.

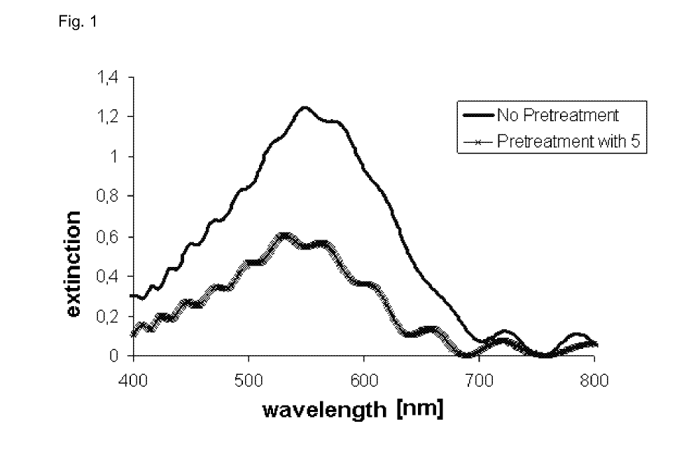

The hydroxamic acids or their salts tested as additives are listed in table 1. The hydroxamic acids 1 to 5 were purchased commercially; the hydroxamates 6 to 10 were prepared from hydroxamic acid 5 by reacting this with NaOH, KOH, LiOH, CsOH or tetrabutylammonium hydroxide. The test results obtained with these additives that were employed via a pre-treatment or post-treatment method are depicted in tables 2, 3 and 4 and also in FIG. 1.

TABLE 1
Additives employed in solar cells that were tested regarding their
energy conversion efficiency η.

| Ex- | |
|---|---|
| ample | |
| No. | Structural Formula |
| 1 | 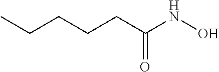 |
| 2 | 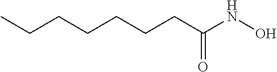 |
| 3 | 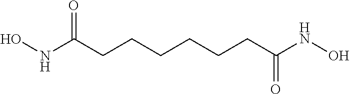 |
| 4 | 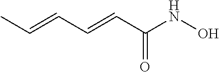 |
| 5 | 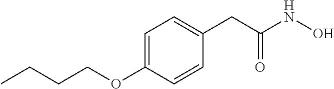 |
| 6 | 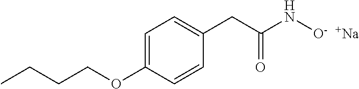 |
| 7 | 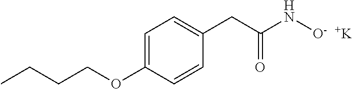 |
| 8 | 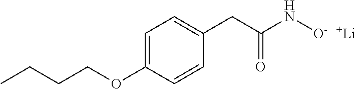 |
| 9 | 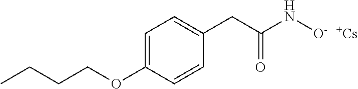 |
| 10 | 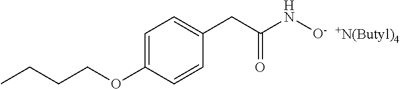 |
| 11 | 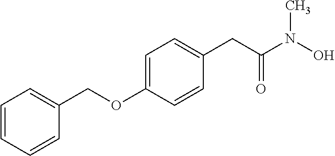 |

TABLE 2
Representative values derived from the current/
voltage characteristics of solar cells radiated with a sun
simulator, where the photosensitive layers of the cells
were subjected to a pre-treatment with
hydroxamic acids depicted in table 1.

| | I_{sc} [mA/cm²] | V_{oc} [mV] | FF [%] | η [%] |
|---|---|---|---|---|
| 1 | −11.0 | 600 | 33 | 2.2 |
| 2 | −10.7 | 620 | 35 | 2.3 |
| 5 | −10.2 | 640 | 49 | 3.1 |
| 11 | −8.8 | 660 | 36 | 2.1 |
| without additive | −5.1 | 580 | 55 | 1.6 |

TABLE 3
Representative values derived from the current/
voltage characteristics of solar cells radiated with a sun
simulator, where the photosensitive layers of
the cells were subjected to a pre-treatment with
hydroxamates depicted in table 1.

| | I_{sc} [mA/cm²] | V_{oc} [mV] | FF [%] | η [%] |
|---|---|---|---|---|
| 6 | −9.4 | 800 | 49 | 3.7 |
| 7 | −5.5 | 860 | 65 | 3.1 |
| 8 | −6.5 | 820 | 69 | 3.7 |
| 9 | −4.5 | 820 | 60 | 2.4 |
| 10 | −11.2 | 700 | 41 | 3.2 |

TABLE 4
Representative values derived from the current/
voltage characteristics of solar cells radiated with a sun
simulator, where the photosensitive layers of
the cells were subjected to an post-treatment with
hydroxamic acids depicted in table 1.

| | I_{sc} [mA/cm²] | V_{oc} [mV] | FF [%] | η [%] |
|---|---|---|---|---|
| 1 | −10.2 | 600 | 40 | 2.4 |
| 2 | −11.2 | 580 | 41 | 2.6 |
| 3 | −7.8 | 640 | 44 | 2.2 |
| 4 | −8.2 | 540 | 39 | 1.7 |
| 5 | −9.1 | 600 | 56 | 3.0 |
| 11 | −8.7 | 620 | 48 | 2.6 |
| without additive | −5.1 | 580 | 55 | 1.6 |

FIG. 1 shows two extinction spectra of a mesoporous TiO₂ layer of 3 μm thickness (as used for the cells described in table 2) treated with the dye ID176. The upper spectrum (“No Pretreatment”) was obtained by treating the TiO₂ layer only with ID176. The lower spectrum (“Pretreatment with 5”) was obtained by treating the TiO₂ layer first with the hydroxamic acid of example 5 (see table 1) and then absorbing ID176 as previously described. Remarkably, similar currents were obtained, although in the second case (pretreatment with 5), less dye was absorbed in the TiO₂ layer than in the first case (no pretreatment).

It is apparent from these results that the efficiency η of the solar cells including an additive according to the invention is improved in comparison to the blank value provided by a cell without an additive. This is mainly due to an increased short circuit current (I_{sc}). This is a surprising finding because it was determined that the absorption of light in the wavelength range of 400 to 700 nm was reduced when the photosensitive layer in addition to the dye also included one of the tested additives. In conclusion, the additives according to the invention result in a distinct increase of the quantum efficiency.

We claim:

1. A process for producing a dye-sensitized photoelectric conversion device comprising a photosensitive layer containing at least one semi-conductive metal oxide on which at least one chromophoric substance is adsorbed, wherein said semiconductive metal oxide is treated with at least one hydroxamic acid and/or at least one salt thereof which are essentially transparent in the electromagnetic wavelength range of 400 to 1000 nm.

2. The process as claimed in claim 1, wherein the at least one hydroxamic acid is a compound of the general formula (I) and the at least one salt thereof is a compound of the general formula (I′) 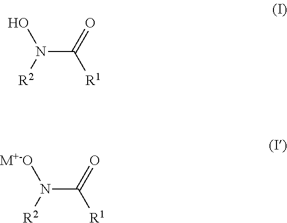
wherein
M⁺ is an alkali metal cation, an equivalent of an earth alkaline metal cation; or an NR′₄ cation, wherein R′ independently of each other are selected from hydrogen, C₁-C₆-alkyl, phenyl and benzyl, pyridinium cation or imidazolium cation, wherein the hetarylic moiety in the last two cations mentioned may be unsubstituted or substituted with 1, 2 or 3 substituents selected from C₁-C₄-alkyl and phenyl;
R¹ is C₁-C₁₈-alkyl, C₂-C₁₂-alkenyl, C₄-C₁₂-alkadienyl, C₆-C₁₂-alkatrienyl, C₂-C₁₂-alkynyl, where 1 to 4 CH₂ groups in the last 5 radicals mentioned may be replaced by O, NH, or S, and/or where the last 5 radicals mentioned may be partly or completely halogenated and/or have 1, 2 or 3 substituents R^{1a}, C₃-C₇-cycloalkyl, C₃-C₇-cycloalkyl-C₁-C₄-alkyl, C₃-C₇-heterocyclyl, C₃-C₇-heterocyclyl-C₁-C₄-alkyl, where cycloalkyl and heterocyclyl in the last 4 radicals mentioned may have 1, 2, 3 or 4 radicals R^{1b},
aryl, hetaryl, aryl-C₁-C₆-alkyl, aryl-C₂-C₆-alkenyl, hetaryl-C₁-C₄-alkyl or hetaryl-C₂-C₆-alkenyl, where aryl and hetaryl in the last 6 radicals mentioned may be unsubstituted or carry 1, 2, 3 or 4 identical or different radicals R^{1c}; where
R^{1a} are selected independently of one another from OH, SH, NO₂, COOH, CHO, NR^{a1}R^{a2}, CN, OCH₂COOH, CO—NH—OH, CO—NH—O⁻ M⁺, C₁-C₁₂-alkoxy, C₁-C₁₂-halolkoxy, C₃-C₇-cycloalkyloxy, C₁-C₁₂-alkylthio, C₁-C₁₂-haloalkylthio, CO—C₁-C₁₂-alkyl, CO—O—C₁-C₁₂-alkyl, CONR^{a3}R^{a4}, aryl, hetaryl, aryl-C₁-C₆-alkoxy or hetaryl-C₁-C₄-alkoxy, where aryl and hetaryl in the last 4 radicals mentioned may be unsubstituted or carry 1, 2, 3 or 4 identical or different radicals R^{1c};
R^{1b} are selected independently of one another from OH, SH, NO₂, COOH, CHO, NR^{b1}R^{b2}, CN, OCH₂COOH, halogen,
aryl, aryl-C₁-C₆-alkyl, aryl-C₁-C₆-alkoxy, where aryl in the last 3 radicals mentioned may be unsubstituted or carry 1, 2, 3 or 4 identical or different radicals R^{1c};
C₁-C₆-alkyl, C₁-C₆-alkoxy, C₁-C₆-alkylthio, where the alkyl moieties in the last 3 substituents mentioned may be partly or completely halogenated and/or have 1, 2 or 3 substituents R^{d1};
CO—C₁-C₆-alkyl, CO—O—C₁-C₆-alkyl or CONR^{b3}R^{b4};
R^{1c} are selected independently of one another from OH, SH, halogen, NO₂, NR^{c1}R^{c2}, CN, COOH, OCH₂COOH, C₁-C₁₂-alkyl, C₁-C₁₂-alkoxy, C₁-C₁₂-alkoxy-C₁-C₆-alkyl, C₁-C₁₂-alkylthio, where the alkyl moieties in the last 4 substituents mentioned may be partly or completely halogenated and/or have 1, 2 or 3 substituents R^{d1},
C₃-C₇-cycloalkyl, C₃-C₇-cycloalkyl-C₁-C₄-alkyl, C₃-C₇-cycloalkyloxy, C₃-C₇-heterocyclyl, C₃-C₇-heterocyclyl-C₁-C₄-alkyl, C₃-C₇-heterocyclyloxy, where cycloalkyl and heterocyclyl in the last 6 radicals mentioned may have 1, 2, 3 or 4 radicals R^{d2},
aryl, hetaryl, O-aryl, O—CH₂-aryl, where the last three radicals mentioned are unsubstituted in the aryl moiety or may carry 1, 2, 3 or 4 radicals R^{1d},
CO—C₁-C₆-alkyl, CO—O—C₁-C₆-alkyl, CONR^{c3}R^{c4},
or two radicals R^{1b} or two radicals R^{1c} bonded to adjacent C atoms form together with the C atoms to which they are bonded a 4, 5, 6 or 7-membered, optionally substituted carbocycle or an optionally substituted heterocycle, which has 1, 2 or 3 different or identical heteroatoms from the group of O, N and S as ring members;
R^{1d} are selected from halogen, OH, SH, NO₂, COOH, C(O)NH₂, CHO, CN, NH₂, OCH₂COOH, C₁-C₆-alkyl, C₁-C₆-haloalkyl, C₁-C₆-alkoxy, C₁-C₆-haloalkoxy, C₁-C₆-alkylthio, C₁-C₆-haloalkylthio, CO—C₁-C₆-alkyl, CO—O—C₁-C₆-alkyl, NH—C₁-C₆-alkyl, NHCHO, NH—C(O)C₁-C₆-alkyl, and SO₂—C₁-C₆-alkyl;
R^{a1}, R^{b1} and R^{c1} are independently of one another H, C₁-C₆-alkyl, C₁-C₆-alkoxy, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, CO—C₁-C₆-alkyl, aryl, hetaryl, O-aryl, OCH₂-aryl, aryl-C₁-C₄-alkyl, hetaryl-C₁-C₄-alkyl, CO-aryl, CO-hetaryl, where aryl and hetaryl in the last 8 radicals mentioned are unsubstituted or have 1, 2 or 3 substituents R^{1d},
R^{a2}, R^{b2} and R^{c2} are independently of one another H, C₁-C₆-alkyl, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, or the two radicals R^{a1} and R^{a2}, or R^{b1} and R^{b2} or R^{c1} and R^{c2} form together with the N atom a 3 to 7-membered, optionally substituted nitrogen heterocycle which may optionally have 1, 2 or 3 further different or identical heteroatoms from the group of O, N and S as ring members,
R^{a3}, R^{b3} and R^{c3} are independently of one another H, C₁-C₆-alkyl, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, and
R^{a4}, R^{b4} and R^{c4} are independently of one another H, C₁-C₆-alkyl, C₁-C₆-haloalkyl, C₁-C₆-alkyl which has 1, 2 or 3 substituents R^{b1}, or C₂-C₆-alkenyl, C₂-C₆-alkynyl, C₃-C₇-cycloalkyl, C₃-C₇-cycloalkyl-C₁-C₄-alkyl, C₃-C₇-heterocycloalkyl-C₁-C₄-alkyl, C₁-C₆-alkoxy-C₁-C₄-alkyl, aryl, aryl-C₁-C₄-alkyl, hetaryl or hetaryl-C₁-C₄-alkyl, where aryl and hetaryl in the last 4 radicals mentioned are unsubstituted or have 1, 2 or 3 substituents R^{1d}, or the two radicals R^{a3} and R^{a4}, or R^{b3} and R^{b4} or R^{c3} and R^{c4} form together with the N atom a 3 to 7-membered, optionally substituted nitrogen heterocycle which may optionally have 1, 2 or 3 further different or identical heteroatoms from the group of O, N, S as ring members;
R^{d1} are selected independently of one another from OH, SH, NO₂, COOH, CHO, NR^{a1}R^{a2}, CN, OCH₂COOH, C₁-C₁₂-alkoxy, C₁-C₁₂-halolkoxy, C₃-C₇-cycloalkyloxy, CO—C₁-C₁₂-alkyl, CO—O—C₁-C₁₂-alkyl, CONR^{a3}R^{a4}, aryl, hetaryl, aryl-C₁-C₆-alkoxy and hetaryl-C₁-C₄-alkoxy, where aryl and hetaryl in the last 4 radicals mentioned may be unsubstituted or carry 1, 2, 3 or 4 identical or different radicals R^{1d};
R^{d2} are selected independently of one another from OH, SH, NO₂, COOH, CHO, NR^{b1}R^{b2}, CN, OCH₂COOH, halogen, aryl, aryl-C₁-C₆-alkyl, aryl-C₁-C₆-alkoxy, where aryl in the last 3 radicals mentioned may be unsubstituted or carry 1, 2, 3 or 4 identical or different radicals R^{1d}, C₁-C₆-alkyl, C₁-C₆-alkoxy, C₁-C₆-alkylthio, where the alkyl moieties in the last 3 substituents mentioned may be partly or completely halogenated and/or have 1, 2 or 3 substituents R^{d1}; and
R² is H, C₁-C₆-alkyl, C₃-C₇-cycloalkyl or phenyl.

3. The process as claimed in claim 2, wherein
M⁺ is a lithium ion, sodium ion, potassium ion, a caesium ion or NR′₄ ion, wherein R′ independently of each other are selected from hydrogen, C₁-C₄-alkyl, and benzyl.

4. The process as claimed in any one of claim 2 or 3, wherein
R² is H, C₁-C₄-alkyl, cyclohexyl or phenyl.

5. The process as claimed in claim 4, wherein
R² is H or methyl.

6. The process as claimed in claim 5, wherein R² is H.

7. The process as claimed in any one of claims 2 to 6, wherein
R¹ is C₁-C₁₀-alkyl, C₂-C₁₀-alkenyl, C₄-C₁₀-alkadienyl, where the last 3 radicals mentioned may be partly or completely halogenated and/or have 1, 2 or 3 substituents R^{1a},
C₃-C₇-cycloalkyl, C₃-C₇-cycloalkyl-C₁-C₄-alkyl, C₃-C₇-heterocyclyl, C₃-C₇-heterocyclyl-C₁-C₄-alkyl, where cycloalkyl and heterocyclyl in the last 4 radicals mentioned may have 1, 2 or 3 radicals R^{1b},
aryl, hetaryl, aryl-C₁-C₆-alkyl or hetaryl-C₁-C₄-alkyl, where aryl and hetaryl in the last 4 radicals mentioned may be unsubstituted or carry 1, 2 or 3 identical or different radicals R^{1c}; where
R^{1a} is selected independently of one another from NO₂, CN, CO—NH—OH, CO—NH—O⁻ M⁺, C₁-C₁₂-alkoxy, C₁-C₁₂-halolkoxy, aryl, hetaryl, aryl-C₁-C₆-alkoxy, or hetaryl-C₁-C₄-alkoxy, where aryl and hetaryl in the last 4 radicals mentioned may be unsubstituted or carry 1, 2 or 3 identical or different radicals R^{1c};
R^{1b} is selected independently of one another from NO₂, CN, halogen, aryl, aryl-C₁-C₆-alkyl, aryl-C₁-C₆-alkoxy, where aryl in the last 3 radicals mentioned may be unsubstituted or carry 1, 2 or 3 identical or different radicals R^{1c}; C₁-C₆-alkyl or C₁-C₆-alkoxy, where the alkyl moieties in the last 2 substituents mentioned may be partly or completely halogenated and/or have 1 or 2 substituents R^{d1},
R^{1c} is selected independently of one another from halogen, NO₂, CN, C₁-C₁₂-alkyl, C₁-C₁₂-alkoxy, C₁-C₁₂-alkoxy-C₁-C₄-alkyl, where the alkyl moieties in the last 3 substituents mentioned may be partly or completely halogenated and/or have 1 or 2 substituents R^{d1},
C₃-C₇-cycloalkyl, C₃-C₇-cycloalkyl-C₁-C₄-alkyl, C₃-C₇-heterocyclyl, C₃-C₇-heterocyclyl-C₁-C₄-alkyl, where the cycloalkyl and heterocyclyl moiety of the last 4 radicals mentioned may have 1, 2 or 3 R^{d2} radicals,
aryl or O—CH₂-aryl, where the last three radicals mentioned are unsubstituted in the aryl moiety or may carry 1, 2 or 3 radicals R^{1d}; and
R^{1d} is selected from halogen, NO₂, CN, NH₂, C₁-C₆-alkyl, C₁-C₆-haloalkyl, C₁-C₆-alkoxy and C₁-C₆-haloalkoxy.

8. The process as claimed in claim 7, wherein
R¹ is C₁-C₁₀-alkyl, C₂-C₁₀-alkenyl or C₄-C₁₀-alkadienyl, where the last 3 radicals mentioned may be substituted with 1, 2 or 3 substituents independently of one another selected from CO—NH—OH,
CO—NH—O⁻ M⁺, C₁-C₆-alkoxy, phenyl and phenyl-C₁-C₆-alkoxy, where phenyl in the last 2 radicals mentioned may be unsubstituted or substituted with 1, 2 or 3 substituents independently of one another selected from C₃-C₁₂-alkyl, C₃-C₁₂-alkoxy, C₃-C₁₂-alkoxy-C₁-C₄-alkyl and phenyl-C₁-C₆-alkoxy.

9. The process as claimed in claim 8, where R¹ is C₃-C₁₀-alkyl, which may be substituted with one group CO—NH—OH or CO—NH—O⁻ M⁺, or is C₄-C₁₀-alkadienyl.

10. The process as claimed in claim 7, where R¹ is benzyl which carries one substituent selected from C₃-C₁₂-alkoxy and benzyloxy.

11. The process as claimed in claim 10, where the substituent is bound in 4-position of the benzyl group.

12. The process as claimed in any one of the preceding claims, wherein the semiconductive metal oxide is treated with the at least one hydroxamic acid or the salt thereof after the chromophoric substance is adsorbed on the semi-conductive metal oxide.

13. The process as claimed in any one of claims 1 to 11, wherein the semiconductive metal oxide is treated with the at least one hydroxamic acid or the salt thereof while the chromophoric substance is adsorbed on the semi-conductive metal oxide.

14. The process as claimed in any one of claims 1 to 11, wherein the semiconductive metal oxide is treated with the at least one hydroxamic acid or the salt thereof before the chromophoric substance is adsorbed on the semi-conductive metal oxide.

15. The process as claimed in any one of the preceding claims wherein the chromophoric substance is selected from metal complex dyes, porphyrin dyes, merocyanine dyes and rylene dyes.

16. The process as claimed in claim 15, wherein the chromophoric substance is selected from ruthenium complex dyes and rylene dyes.

17. The process as claimed in any one of the preceding claims, wherein the semiconductive metal oxide contained in the photosensitive layer is nanoporous TiO₂.

18. The process as claimed in any one of the preceding claims, comprising the following steps:
i) providing an electrically conductive layer;
ii) optionally depositing an undercoating layer thereon,
iii) depositing a photosensitive layer on the electrically conductive layer or, if present, the undercoating layer, wherein the photosensitive layer contains a semi-conductive metal oxide as defined in any of claim 1 or 17 that is sensitized by a chromophoric substance as defined in any of claim 1, 15 or 16 and treated with at least one hydroxamic acid or a salt thereof as defined in any of claims 1 to 11;
iv) depositing a charge transfer layer on the photosensitive layer; and
v) depositing a counter electrically conductive layer on the charge transfer layer.

19. The process as claimed in claim 18, wherein either one or both of the electrically conductive layer and the counter electrically conductive layer are substantially transparent.

20. The process as claimed in any one of claim 18 or 19, wherein the electrically conductive layer contains an electrically conductive metal oxide.

21. The process as claimed in 20, wherein the electrically conductive metal oxide is tin oxide doped with fluorine, antimony or indium.

22. The process as claimed in any one of claims 18 to 21, wherein undercoating layer comprises a semi-conductive, optionally doped metal oxide.

23. The process as claimed in claim 22, wherein the semi-conductive metal oxide is TiO₂.

24. The process as claimed in any one of claims 18 to 23, wherein the chromophoric substance is adsorbed on the semi-conductive metal oxide of the photosensitive layer.

25. The process as claimed in any one of the preceding claims, wherein the at least one hydroxamic acid or a salt thereof is adsorbed on the semi-conductive metal oxide of the photosensitive layer.

26. The process as claimed in any one of claims 14 to 21, wherein the charge transfer layer includes an ion conductive electrolyte composition or a hole-transporting material.

27. The process as claimed in claim 26, wherein the charge transfer layer is solid.

28. The process as claimed in any one of claim 26 or 27, wherein the charge transfer layer includes a spirobifluorene derivative as the hole-transporting material.

29. The process as claimed in claim 28, wherein the charge transfer layer also includes a salt.

30. The process as claimed in claim 29, wherein the salt is Li[CF₃SO₂)N].

31. The process as claimed in any one of claims 18 to 30, wherein the counter electrically conductive layer comprises a metal.

32. The process as claimed in claim 31, wherein the metal is silver or gold.

33. A dye-sensitized photoelectric conversion device obtainable by a process according to any one of claims 1 to 32.

34. A solar cell which comprises the photoelectric conversion device according to claim 33.

35. The use of hydroxamic acids and/or of salts thereof as defined in any of claims 1 to 11 for enhancing the energy conversion efficiency η of dye-sensitized photoelectric conversion devices.
